(19) United States
(12) Patent Application Publication
(10) Pub. No.: US 2025/0063875 A1
(43) Pub. Date: Feb. 20, 2025

(54) DISPLAY PANEL, DISPLAY DEVICE, AND SPLICING DISPLAY DEVICE

(71) Applicant: Tianma Advanced Display Technology Institute (Xiamen) Co., Ltd., Xiamen (CN)

(72) Inventors: Zhenyu JIA, Xiamen (CN); Liwei ZHANG, Xiamen (CN); Kerui XI, Xiamen (CN); Tianyi WU, Xiamen (CN); Bo ZHOU, Xiamen (CN); Yingteng ZHAI, Xiamen (CN); Xiuli WANG, Xiamen (CN); Xueling LI, Xiamen (CN)

(21) Appl. No.: 18/932,699

(22) Filed: Oct. 31, 2024

(30) Foreign Application Priority Data
Jun. 25, 2024 (CN) 202410826330.X

(51) Int. Cl. H01L 33/62; G09G 3/32; H01L 25/075

(52) U.S. Cl. CPC H01L 33/62; G09G 3/32; H01L 25/0753; G09G 2300/026; G09G 2300/0439

(57) ABSTRACT

A display panel, a display device, and a splicing display device are provided. The display panel includes pixels including subpixels, the subpixel includes a pixel circuit and a light-emitting element that are electrically connected to each other. In a pixel, light-emitting elements of the subpixels are arranged along a first direction, and pixel circuits of the subpixels are arranged along the first direction. In at least one pixel, an arrangement order of the light-emitting elements is different from an arrangement order of the pixel circuits; or arrangement orders of the pixel circuits in at least two pixels are different from each other, or arrangement orders of the light-emitting elements in at least two pixels are different from each other.

### CROSS-REFERENCE TO RELATED APPLICATIONS

The present disclosure claims priority to Chinese Application No. 202410826330.X with the application title of “DISPLAY PANEL, DISPLAY DEVICE, AND SPLICING DISPLAY DEVICE”, filed on Jun. 25, 2024, the content of which is incorporated herein by reference in its entirety.

### TECHNICAL FIELD

The present disclosure relates to the field of display technologies, especially relates to a display panel, a display device, and a splicing display device.

### BACKGROUND

Light-emitting Diode (LED) display panels are widely used in various types of display devices due to their advantages of high brightness, good luminous efficiency and low power consumption. However, in related art, these display panels have problems such as difficulties in arranging connection wires when realizing the connection between pixel circuits and light-emitting elements.

### SUMMARY

In view of the above, embodiments of the present disclosure provide a display panel, a display device, and a splicing display device.

Some embodiments of the present disclosure provide a display panel including pixels, a pixel includes subpixels, and a subpixel includes a pixel circuit and a light-emitting element that are electrically connected to each other. In the pixel, the light-emitting elements of the subpixels are arranged along a first direction, and the pixel circuits of the subpixels are arranged along the first direction. In at least one pixel of the pixels, an arrangement order of the light-emitting elements is different from an arrangement order of the pixel circuits; or an arrangement order of the pixel circuits in one pixel of the pixels is different from an arrangement order of the pixel circuits in another pixel of the pixels; or an arrangement order of the light-emitting elements in one pixel of the pixels are different is different from an arrangement order the light-emitting elements in another pixel of the pixels.

Some embodiments of the present disclosure provides a display device including a display panel. The display panel includes pixels, a pixel includes subpixels, and a subpixel includes a pixel circuit and a light-emitting element that are electrically connected to each other. In the pixel, the light-emitting elements of the subpixels are arranged along a first direction, and the pixel circuits of the subpixels are arranged along the first direction. In at least one pixel of the pixels, an arrangement order of the light-emitting elements is different from an arrangement order of the pixel circuits; or an arrangement order of the pixel circuits in one pixel of the pixels is different from an arrangement order of the pixel circuits in another pixel of the pixels; or an arrangement order of the light-emitting elements in one pixel of the pixels are different is different from an arrangement order the light-emitting elements in another pixel of the pixels.

Some embodiments of the present disclosure provide a splicing display device including at least two display panels. The display panel includes pixels, a pixel includes subpixels, and a subpixel includes a pixel circuit and a light-emitting element that are electrically connected to each other. In the pixel, the light-emitting elements of the subpixels are arranged along a first direction, and the pixel circuits of the subpixels are arranged along the first direction. In at least one pixel of the pixels, an arrangement order of the light-emitting elements is different from an arrangement order of the pixel circuits; or an arrangement order of the pixel circuits in one pixel of the pixels is different from an arrangement order of the pixel circuits in another pixel of the pixels; or an arrangement order of the light-emitting elements in one pixel of the pixels are different is different from an arrangement order the light-emitting elements in another pixel of the pixels.

### BRIEF DESCRIPTION OF DRAWINGS

To more clearly illustrate technical solutions of the embodiments of the present disclosure, drawings required for the embodiments will be briefly introduced below. The drawings described below are merely some embodiments of the present disclosure. For those skilled in the art, other drawings may be obtained based on these drawings.

FIG. 1 is a schematic diagram of a display panel in related technologies;

FIG. 2 is a schematic diagram of a single pixel in related technologies;

FIG. 3 is another schematic diagram of a single pixel in related technologies;

FIG. 4 is another schematic diagram of a single pixel in related technologies;

FIG. 5 is another schematic diagram of a single pixel in related technologies;

FIG. 6 is a schematic diagram of a display panel provided by embodiments of the present disclosure;

FIG. 7 is another schematic diagram of a display panel provided by embodiments of the present disclosure;

FIG. 8 is another schematic diagram of a display panel provided by embodiments of the present disclosure;

FIG. 9 is a cross-sectional schematic diagram of a display panel provided by embodiments of the present disclosure;

FIG. 10 is another cross-sectional schematic diagram of a display panel provided by embodiments of the present disclosure;

FIG. 11 is a top view of light-emitting elements, first electrodes, second electrodes, and a first power supply signal line provided by embodiments of the present disclosure;

FIG. 12 is another top view of light-emitting elements, first electrodes, second electrodes, and a first power supply signal line provided by embodiments of the present disclosure;

FIG. 13 is a schematic diagram of a pixel provided by embodiments of the present disclosure;

FIG. 14 is another schematic diagram of a display panel provided by embodiments of the present disclosure;

FIG. 15 is a schematic diagram of a first pixel provided by embodiments of the present disclosure;

FIG. 16 is another schematic diagram of a display panel provided by embodiments of the present disclosure;

FIG. 17 is another schematic diagram of a display panel provided by embodiments of the present disclosure;

FIG. 18 is another schematic diagram of a display panel provided by embodiments of the present disclosure;

FIG. 19 is another schematic diagram of a display panel provided by embodiments of the present disclosure;

FIG. 20 is a schematic diagram of a second-type pixel provided by an embodiment of the present disclosure;

FIG. 21 is a schematic diagram of a layer structure of a second-type pixel provided by embodiments of the present disclosure;

FIG. 22 is a schematic diagram of a first-type first pixel provided by embodiments of the present disclosure;

FIG. 23 is a schematic diagram of a layer structure of a first-type first pixel provided by embodiments of the present disclosure;

FIG. 24 is a schematic diagram of a second-type first pixel provided by embodiments of the present disclosure;

FIG. 25 is a schematic diagram of a layer structure of a second-type first pixel provided by embodiments of the present disclosure;

FIG. 26 is a schematic diagram of a third-type first pixel provided by embodiments of the present disclosure;

FIG. 27 is a schematic diagram of a layer structure of the third-type first pixel provided by embodiments of the present disclosure;

FIG. 28 is a schematic diagram of a fourth-type first pixel provided by embodiments of the present disclosure;

FIG. 29 is a schematic diagram of a layer structure of the fourth-type first pixel provided by embodiments of the present disclosure;

FIG. 30 is another schematic diagram of a display panel provided by embodiments of the present disclosure;

FIG. 31 is a schematic diagram of a second pixel provided by embodiments of the present disclosure;

FIG. 32 is a schematic diagram of a layer structure of the second pixel provided by embodiments of the present disclosure;

FIG. 33 is a schematic diagram of a layer structure of a display panel provided by embodiments of the present disclosure;

FIG. 34 is another schematic diagram of a display panel provided by embodiments of the present disclosure;

FIG. 35 is another schematic diagram of a display panel provided by embodiments of the present disclosure;

FIG. 36 is a schematic diagram of a layer structure of a display panel provided by embodiments of the present disclosure;

FIG. 37 is a cross-sectional view of FIG. 36 along line A1-A2;

FIG. 38 is a schematic diagram of another layer structure of a display panel provided by embodiments of the present disclosure;

FIG. 39 is another schematic diagram of a display panel provided by embodiments of the present disclosure;

FIG. 40 is a circuit schematic diagram of a pixel circuit provided by embodiments of the present disclosure;

FIG. 41 is a schematic diagram of a layer structure of a pixel circuit provided by embodiments of the present disclosure;

FIG. 42 is another schematic diagram of a display panel provided by embodiments of the present disclosure;

FIG. 43 is another schematic diagram of a display panel provided by embodiments of the present disclosure;

FIG. 44 is a schematic diagram of a display device provided by embodiments of the present disclosure; and

FIG. 45 is a schematic diagram of a spliced display device provided by embodiments of the present disclosure.

### DESCRIPTION OF EMBODIMENTS

In order to better understand the technical solutions of the present disclosure, the embodiments of the present disclosure will be described in detail below with reference to the drawings.

It should be clear that the described embodiments are merely some of the embodiments of the present disclosure rather than all of the embodiments. Based on the embodiments of the present disclosure, all other embodiments obtained by those skilled in the art fall within the scope of the present disclosure.

The terms used in the embodiments of the present disclosure are merely for the purpose of describing specific embodiments, rather than limiting the present disclosure. The singular forms “a”, “an”, “said” and “the” used in the embodiments of the present disclosure and claims shall be interpreted as also including the plural forms, unless indicated otherwise in the context.

It should be understood that the term “and/or” used herein is merely a description of the associative relationship between associated objects, indicating that there are three relationships. For example, A and/or B may indicate A alone, both A and B, or B alone. Additionally, the character “/” used herein generally indicates that the associated objects are in an “or” relationship.

With the continuous development of display technologies, the design of the relative position relationship between pixel circuits and light-emitting elements in a pixel has become more flexible.

As shown in FIG. 1, which is a schematic diagram of a display panel in related technologies, the display panel includes pixels 101, and the pixel 101 includes multiple subpixels 102. The subpixel 102 includes a pixel circuit 103 and a light-emitting element 104 that are electrically connected to each other. In at least one pixels 101, the pixel circuit 103 and the light-emitting element 104 corresponding to the pixel circuit 103 are relatively far away from each other, and are connected to each other through a connecting line.

However, based on the panel structure in the related art, the arrangement of the connecting lines is relatively difficult and prone to causing some adverse issues.

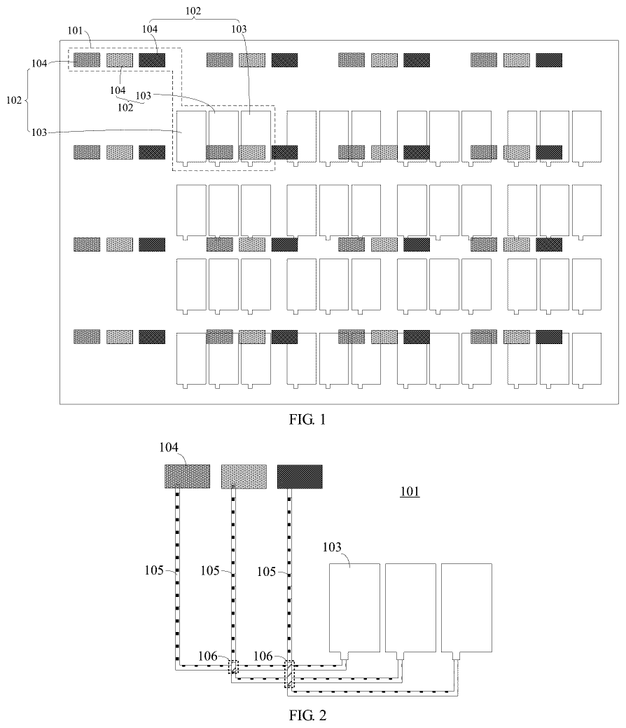

FIG. 2 is a schematic diagram of a single pixel 101 in related technologies, and FIG. 3 is another schematic diagram of a single pixel 101 in related technologies. As shown in FIG. 2 and FIG. 3, in the pixel 101, when the connecting lines 105 led out from different pixel circuits 103 extend towards the light-emitting elements 104 respectively corresponding to these pixel circuits 103, multiple connecting lines 105 overlap. To avoid short circuits, at least one connecting line 105 is provided with a cross-bridge 106 for wire switching.

However, in this way, a larger number of connecting lines 105 will occupy at least two metal layers. In this way, not only the layer design for these connecting lines 105 is complex, but also arrangements of lines located in a same layer as the connecting lines 105 will be affect by the arrangements of connecting lines 105. For instance, in the layout design, it is necessary for the metal layers to consider whether position conflicts between the connecting lines 105 and other wires, leading to difficulties in arrangement of the connecting lines 105.

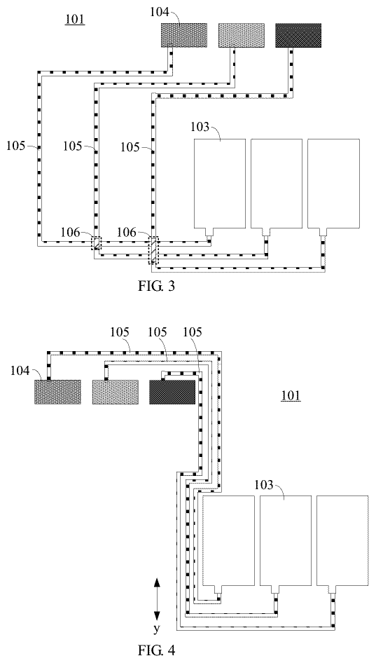

And if it is desired to avoid overlapping between the connecting lines 105, the connecting lines 105 may avoid each other by bypassing as shown in FIG. 4 and FIG. 5, where FIG. 4 is another schematic diagram of a single pixel 101 in related technologies, and FIG. 5 is yet another schematic diagram of a single pixel 101 in related technologies. However, although such configuration may allow the connecting lines 105 to adopt a single-layer design, simplifying the design of their own layers, the extension method of the connecting lines 105 becomes very complicated. Moreover, the bypassing ways of connecting lines 105 corresponding to different pixels 101 are also different, which makes the design of connecting lines 105 difficult. After the connecting lines 105 bypass, they will still occupy a large arrangement space in the metal layer, thus still affecting the arrangements of many other lines in a same layer. For example, when the connecting lines 105 bypass, a longer longitudinal segment extending along the direction y is formed, which will occupy the arrangement space of other longitudinal lines extending along the direction y in the metal layer, leading to layer position conflicts between different lines.

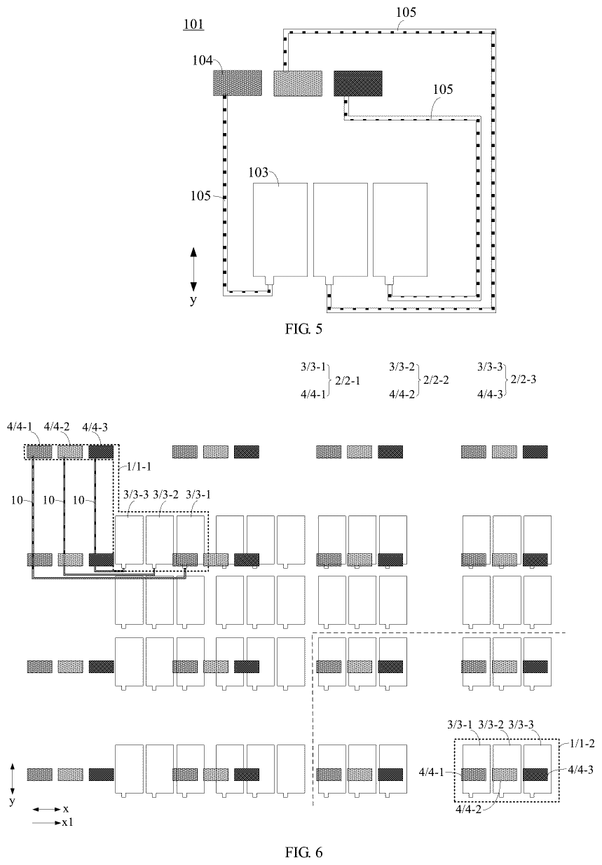

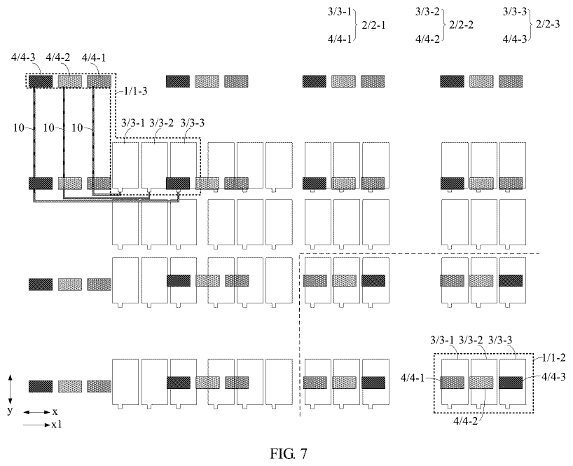

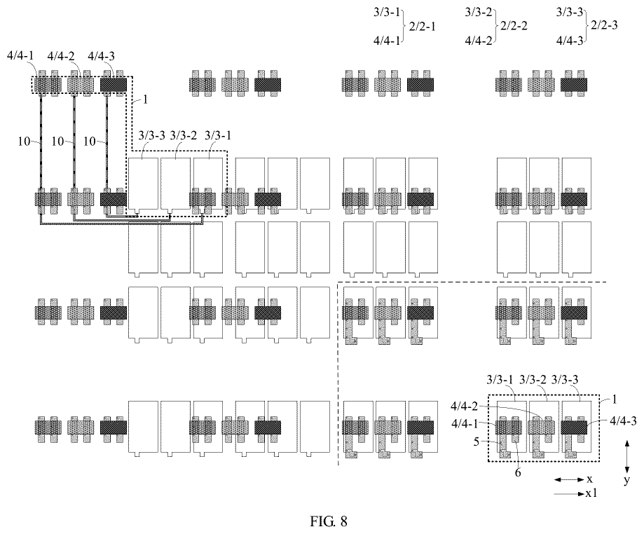

In this regard, some embodiments of the present disclosure provide a display panel as shown in FIGS. 6 and 7. FIG. 6 is a schematic diagram of a display panel provided by embodiments of the present disclosure, and FIG. 7 is another schematic diagram of a display panel provided by embodiments of the present disclosure. The display panel includes multiple pixels 1, and the pixel 1 may include multiple subpixels 2 of different colors. The subpixel 2 includes a pixel circuit 3 and a light-emitting element 4 that are electrically connected to each other. In the embodiments of the present disclosure, the light-emitting element 4 may be an LED, for example, a Micro LED or a Mini LED.

Within the pixel 1, the light-emitting elements 4 of the multiple subpixels 2 are arranged along a first direction x, and the pixel circuits 3 of the multiple subpixels 2 are arranged along the first direction x. In at least one pixel 1, an arrangement order of the multiple light-emitting elements 4 is different from an arrangement order of the multiple pixel circuits 3; or arrangement orders of the multiple pixel circuits 3 in at least two pixels 1 are different from each other; or arrangement orders of the multiple light-emitting elements 4 in at least two pixels 1 are different from each other.

In the embodiments of the present disclosure, both the arrangement order of the light-emitting elements 4 and the arrangement order of the pixel circuits 3 may be represented by an arrangement order of colors. It may be understood that the pixel 1 includes multiple subpixels 2 in different colors, which means that the light-emitting elements 4 of the multiple subpixels 2 emit light with different colors, i.e., the multiple light-emitting elements 4 of the pixel 1 correspond to multiple different colors respectively. Accordingly, the pixel circuits 3 of the multiple subpixels 2 are electrically connected to the light-emitting elements 4 emitting light with different colors respectively and are configured to provide a driving current for different color brightness. Therefore, the multiple pixel circuits 3 in the pixel 1 also correspond to multiple different colors respectively, and the colors corresponding to the pixel circuits 3 are the same as the colors corresponding to the light-emitting elements 4 that connected to the pixel circuits 3.

For example, as shown in FIGS. 6 and 7, the multiple subpixels 2 in the pixel 1 include a first subpixel 2-1, a second subpixel 2-2 and a third subpixel 2-3 that have different colors. The following embodiments of the present disclosure will take the first subpixel 2-1 as a red subpixel, the second subpixel 2-2 as a green subpixel, and the third subpixel 2-3 as a blue subpixel as examples.

In the first subpixel 2-1, the pixel circuit 3 and the light-emitting element 4 are a first pixel circuit 3-1 and a first light-emitting element 4-1 respectively. Both the first light-emitting element 4-1 and the first pixel circuit 3-1 correspond to red color. In the second subpixel 2-2, the pixel circuit 3 and the light-emitting element 4 are a second pixel circuit 3-2 and a second light-emitting element 4-2 respectively. Both the second light-emitting element 4-2 and the second pixel circuit 3-2 correspond to green color. In the third subpixel 2-3, the pixel circuit 3 and the light-emitting element 4 are a third pixel circuit 3-3 and a third light-emitting element 4-3 respectively. Both the third light-emitting element 4-3 and the third pixel circuit 3-3 correspond to blue color.

When the first light-emitting element 4-1, the second light-emitting element 4-2, and the third light-emitting element 4-3 are arranged in different orders, each arrangement order corresponds to an order of multiple colors. Similarly, when the first pixel circuit 3-1, the second pixel circuit 3-2, and the third pixel circuit 3-3 are arranged in different orders, each arrangement order thereof also corresponds to an order of multiple colors.

For instance, when the first light-emitting element 4-1, the second light-emitting element 4-2, and the third light-emitting element 4-3 are arranged sequentially, the order of multiple colors corresponding to the multiple light-emitting elements 4 in the pixel 1 is “red-green-blue”. When the second light-emitting element 4-2, the first light-emitting element 4-1, and the third light-emitting element 4-3 are arranged sequentially, the order of multiple colors corresponding to the multiple light-emitting elements 4 in the pixel 1 becomes “green-red-blue”.

When the first pixel circuit 3-1, the second pixel circuit 3-2, and the third pixel circuit 3-3 are arranged sequentially, the order of multiple colors corresponding to the multiple pixel circuits 3 in the pixel 1 is “red-green-blue”. When the second pixel circuit 3-2, the first pixel circuit 3-1, and the third pixel circuit 3-3 are arranged sequentially, the order of multiple colors corresponding to the multiple pixel circuits 3 in the pixel 1 becomes “green-red-blue”.

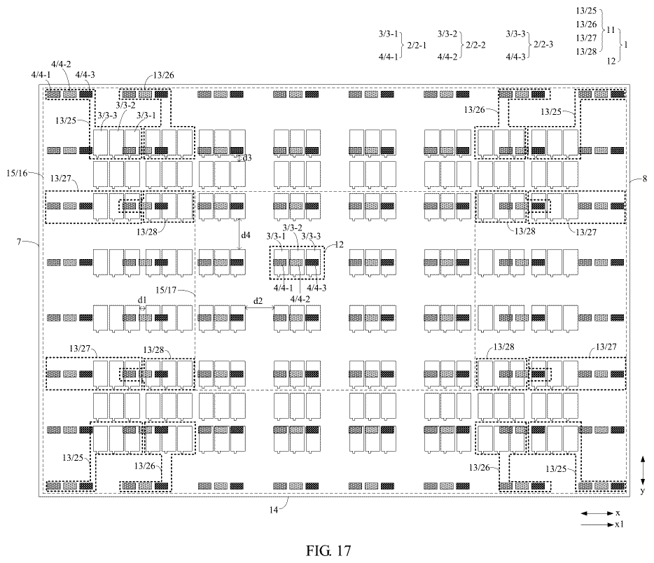

The arrangement directions mentioned in the present disclosure refer to those with clear orientations. For instance, referring to FIG. 17, the display panel includes a first edge 7 and a second edge 8 that are opposite to each other along a first direction x. The direction from the first edge 7 to the second edge 8 is defined as a third direction x1. The arrangement order of the pixel circuits 3, the arrangement order of the light-emitting elements 4, and the arrangement order of the colors, as mentioned in the embodiments of the present disclosure, are all the arrangement orders in the third direction x1.

Based on the above analysis, the aforementioned statement “in at least one pixel 1, the arrangement order of the multiple light-emitting elements 4 is different from the arrangement order of the multiple pixel circuits 3” may also be expressed as “in at least one pixel 1, the arrangement order of multiple colors corresponding to the multiple light-emitting elements 4 is different from the arrangement order of multiple colors corresponding to the multiple pixel circuits 3”. Based on this feature, in one setting mode, referring to the pixel 1-1 in FIG. 6, in the pixel 1-1, the first light-emitting element 4-1, the second light-emitting element 4-2, and the third light-emitting element 4-3 are arranged sequentially, the third pixel circuit 3-3, the second pixel circuit 3-2, and the first pixel circuit 3-1 are arranged sequentially, in this case, the arrangement order of multiple colors corresponding to the multiple light-emitting elements 4 in the pixel 1-1 is “red-green-blue”, and the arrangement order of multiple colors corresponding to the multiple pixel circuits 3 in the pixel 1-1 is “blue-green-red”.

The aforementioned statement “the arrangement orders of the multiple pixel circuits 3 in at least two pixels 1 are different from each other” may also be expressed as “the arrangement orders of multiple colors corresponding to the multiple pixel circuits 3 in at least two pixels 1 are different from each other “. Based on such configuration, in some embodiments, referring to the pixels 1-1 and 1-2 in FIG. 6, the first pixel circuit 3-1, the second pixel circuit 3-2, and the third pixel circuit 3-3 in the pixel 1-2 are arranged sequentially, In this case, the arrangement order of multiple colors corresponding to the multiple pixel circuits 3 in the pixel 1-2 is “red-green-blue”. The third pixel circuit 3-3, the second pixel circuit 3-2, and the first pixel circuit 3-1 in the pixel 1-1 are arranged sequentially, In this case, the arrangement order of multiple colors corresponding to the multiple pixel circuits 3 in the pixel 1-1 is “blue-green-red”.

The aforementioned statement “the arrangement orders of the multiple light-emitting elements 4 in at least two pixels 1 are different from each other” may also be expressed as “the arrangement orders of multiple colors corresponding to the multiple light-emitting elements 4 in at least two pixels 1 are different from each other “. Based on such configuration, in some embodiments, referring to the pixels 1-3 and 1-2 in FIG. 7, the first light-emitting element 4-1, the second light-emitting element 4-2, and the third light-emitting element 4-3 in the pixel 1-2 are arranged sequentially, in this case, the arrangement order of multiple colors corresponding to the multiple light-emitting elements 4 in the pixel 1-2 is “red-green-blue”. The third light-emitting element 4-3, the second light-emitting element 4-2, and the first light-emitting element 4-1 in the pixel 1-3 are arranged sequentially, in this case, the arrangement order of multiple colors corresponding to the multiple light-emitting elements 4 in pixel 1-3 is “blue-green-red.

The pixel circuit corresponding to the red light-emitting element in the present disclosure may be temporarily referred to as a red pixel circuit, which does not mean that the color of this pixel circuit is red, instead that it controls the red light-emitting element to emit light. In the arrangement order of pixel circuits mentioned in the present disclosure, when referring that the arrangement order of colors of the pixel circuits differs, the colors of the pixel circuits are represented by the color of the electrically connected light-emitting elements corresponding to the pixel circuits.

In the embodiments of the present disclosure, the arrangement order of the pixel circuits 3 and/or the arrangement order of the light-emitting elements 4 in at least some pixels 1 is adjusted. This adjustment may specifically be applied to those pixels 1 where the pixel circuits 3 and the light-emitting elements 4 need to be connected through first connecting portions 10, so as to make the layout design of the first connecting portions 10 more flexible. For example, when the pixel circuits 3 and the light-emitting elements 4 in some pixels 1 are relatively far apart, as shown in FIGS. 2, 4 and 6, and compared with the related technologies in which the pixel circuits 3 and the light-emitting elements 4 are arranged in conventional orders, the embodiments of the present disclosure, after changing the arrangement order of the pixel circuits 3 and/or the light-emitting elements 4, allow the multiple first connecting portions 10 corresponding to these pixels 1 to avoid each other without bypassing, thereby preventing overlapping.

Therefore, by adopting the technical solutions provided by the embodiments of the present disclosure, the arrangements of the first connecting portions 10 corresponding to the pixels 1 may be optimized. On the premise of avoiding bypassing of the first connecting portions 10 as much as possible, more first connecting portions 10 may be designed with only a single layer. On one hand, the layer design of the first connecting portions 10 can be simplified without cross-bridges for bypassing. On the other hand, the number of metal layers occupied by the first connecting portions 10 can be reduced. Since there is no need for bypassing, the arrangement space occupied by the first connecting portions 10 in the metal layers is also smaller, thereby effectively improving the issue of difficult arrangement of the first connecting portions 10 caused by position conflicts between the first connecting portions 10 and other lines in the same layer. The shorter length of the first connecting portions 10 also reduces their load, minimizing the voltage drop of the signals transmitted on the first connecting portions 10.

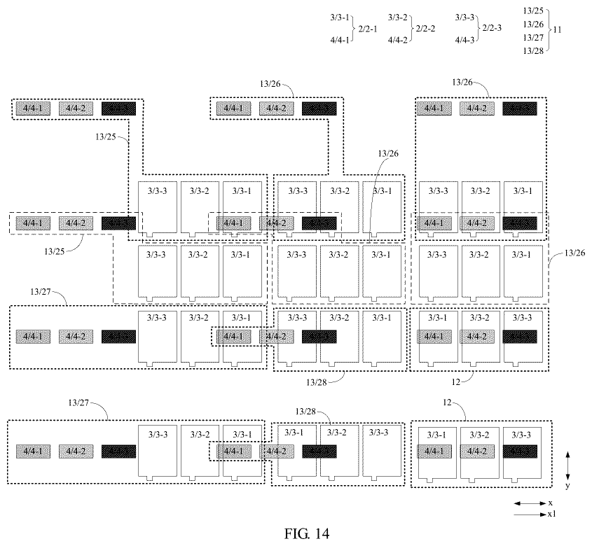

In some embodiments of the present disclosure, combining with FIGS. 14, 16 and 22-29, the pixels 1 includes a first-type pixel 11 and a second-type pixel 12, and a distance between the pixel circuit 3 and its corresponding light-emitting element 4 in the first-type pixel 11 is greater than a distance between the pixel circuit 3 and its corresponding light-emitting element 4 in the second-type pixel 12.

The first-type pixels 11 include a first pixel 13. In a first pixel 13, the pixel circuit 3 and its corresponding light-emitting element 4 are connected to each other by a first connecting portion 10.

In the first pixel 13, the arrangement order of multiple colors corresponding to multiple light-emitting elements 4 is different from that corresponding to the multiple pixel circuits 3. In some embodiments, the arrangement order of multiple colors corresponding to the multiple pixel circuits 3 in the first pixel 13 is different from the arrangement order of multiple colors in the second-type pixel 12, or the arrangement order of multiple colors corresponding to the multiple light-emitting elements 4 in the first pixel 13 is different from the arrangement order of multiple colors in the second-type pixel 12.

Compared with the second-type pixel 12, by adjusting the arrangement order of the pixel circuits 3 and/or the light-emitting elements 4 in the first pixel 13, the design of the first connecting portions 10 corresponding to the first pixel 13 may become relatively flexible. The first connecting portions 10 may avoid from each without bypassing, leading to a more optimized arrangement and layer design of the first connecting portions 10.

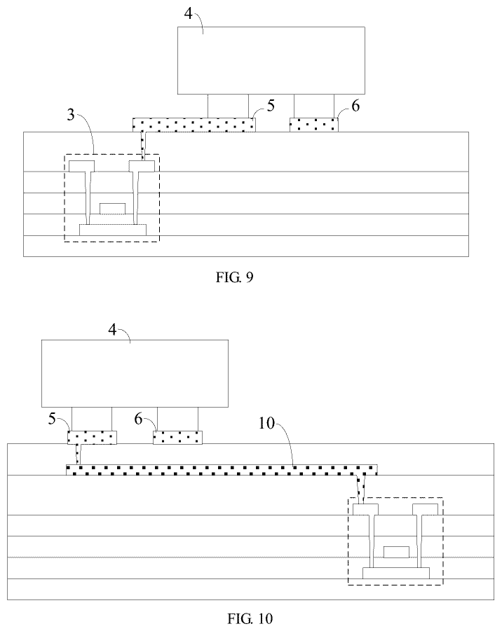

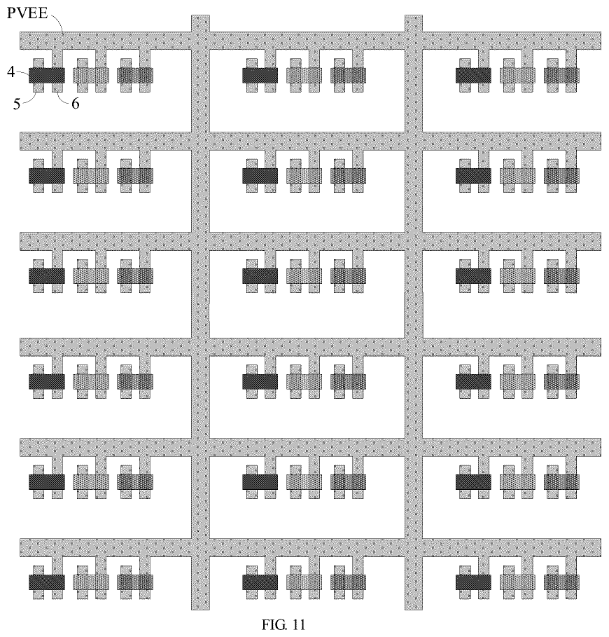

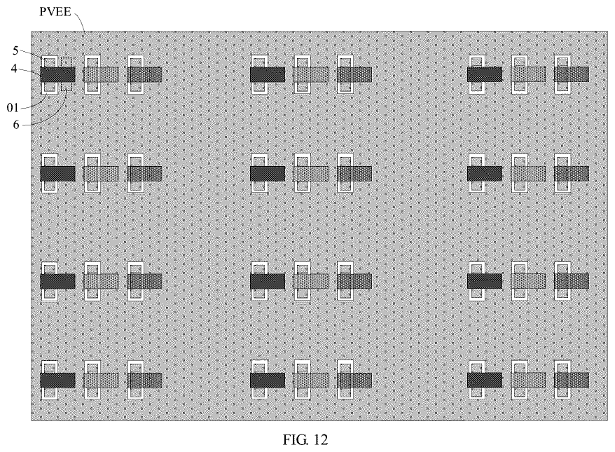

FIG. 8 is another schematic diagram of the display panel provided by embodiments of the present disclosure, FIG. 9 is a cross-sectional schematic diagram of the display panel provided by embodiments of the present disclosure, and FIG. 10 is another cross-sectional schematic diagram of the display panel provided by embodiments of the present disclosure. The connection of the light-emitting elements 4 is shown in FIGS. 8 to 10, the display panel can include a first electrode 5, a second electrode 6, and a first power supply signal line (not shown in FIGS. 8 and 9). The first electrode 5 is electrically connected to both the pixel circuit 3 and a first electrode of the light-emitting element 4, and the second electrode 6 is electrically connected to both the first power supply signal line and a second electrode of the light-emitting element 4. As shown in FIG. 9, in some pixels, the corresponding first electrode 5 is directly electrically connected to the pixel circuit 3. As shown in FIG. 10, in some pixels, the corresponding first electrode 5 is electrically connected to the pixel circuit 3 through the first connecting portion 10.

In some embodiments of the present disclosure, the first power supply signal line may be arranged in a same layer as the first electrode 5 and the second electrode 6. FIG. 11 is a top view of the light-emitting elements 4, the first electrode 5, the second electrode 6 and the first power supply signal line PVEE provided by embodiments of the present disclosure. In some embodiments, as shown in FIG. 11, the first power supply signal line PVEE may be a grid-shaped structure. In this case, multiple second electrodes 6 are all connected to the first power supply signal line PVEE. FIG. 12 is another top view of the light-emitting element 4, the first electrode 5, the second electrode 6 and the first power supply signal line PVEE provided by embodiments of the present disclosure. In some embodiments, as shown in FIG. 12, the first power supply signal line PVEE may also be a planar structure with a hollow 01. The first electrodes 5 are located within the hollow 01 and are electrically insulated from the first power supply signal line PVEE. In this case, part of the first power supply signal line PVEE is reused as the second electrode 6.

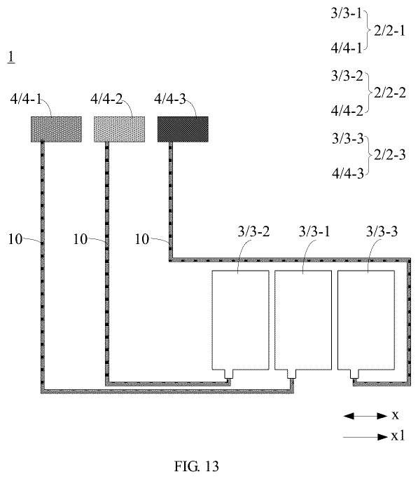

FIG. 13 is a schematic diagram of a pixel 1 provided by embodiments of the present disclosure. In some embodiments, as shown in FIG. 13, multiple subpixels 2 in the pixel 1 include a first subpixel 2-1, a second subpixel 2-2, and a third subpixel 2-3. In at least one pixel 1, the light-emitting elements 4 of the first subpixel 2-1 are adjacent to the light-emitting elements 4 in the second subpixel 2-2, and the pixel circuits 3 of the first subpixel 2-1 are adjacent to the pixel circuits 3 of the second subpixel 2-2. In the first subpixel 2-1 and the second subpixel 2-2, the arrangement order of the light-emitting elements 4 is opposite to the arrangement order of the pixel circuits 3. That is, in the first subpixel 2-1 and the second subpixel 2-2, the arrangement order of two colors corresponding to the light-emitting elements 4 is opposite to the arrangement order of two colors corresponding to the pixel circuits 3.

For example, the first light-emitting element 4-1, the second light-emitting element 4-2, and the third light-emitting element 4-3 are arranged sequentially, and the arrangement order of multiple colors corresponding to the multiple light-emitting elements 4 is “red-green-blue”. The second pixel circuit 3-2, the first pixel circuit 3-1, and the third pixel circuit 3-3 are arranged sequentially, and the arrangement order of the multiple colors corresponding to the multiple pixel circuits 3 is “green-red-blue”.

Comparing FIGS. 2, 4, and 13 with the related technologies in which the pixel circuits 3 and the light-emitting elements 4 are arranged in conventional orders, the embodiments of the present disclosure, after the opposite design of the arrangement orders of the pixel circuits 3 and/or the light-emitting elements 4 in the first subpixel 2-1 and the second subpixel 2-2, at most, only allows the first connecting portions 10 corresponding to the third pixel circuit 3-3 to bypass in the pixel 1 to ensure no overlap among the three first connecting portions 10, leading to an optimized arrangement of the first connecting portions 10.

For at least one pixel 1, when the arrangement orders of the light-emitting elements 4 and the pixel circuits 3 in at least two subpixels 2 in the pixels 1 are inconsistent, and in some embodiments, the arrangement orders of the multiple light-emitting elements 4 in different pixels 1 may be kept the same, and only the arrangement orders of the multiple pixel circuits 3 in the pixels 1 are adjusted. In this way, the light-emitting elements 4 of all the pixels 1 may follow a unified arrangement order, eliminating local display differences and enhancing the display effect of the display panel.

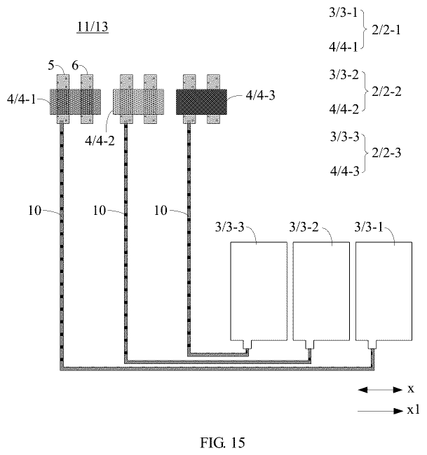

Certainly, in some embodiments of the present disclosure, for at least one pixel 1, when the arrangement orders of the light-emitting elements 4 and pixel circuits 3 of at least two subpixels 2 in the pixel 1 are inconsistent, the light-emitting elements 4 and the pixel circuits 3 in this pixel 1 may also adopt a design of an opposite order, which will result in an even better arrangement of the first connecting portions 10. For instance, referring to the first pixel 13 shown in FIGS. 14 and 15, within the first pixel 13, the first light-emitting element 4-1, the second light-emitting element 4-2, and the third light-emitting element 4-3 are arranged sequentially. In this case, the arrangement order of the multiple colors corresponding to the multiple light-emitting elements 4 is “red-green-blue”, the third pixel circuit 3-3, the second pixel circuit 3-2, and the first pixel circuit 3-1 are arranged sequentially, and the arrangement order of the multiple colors corresponding to the multiple pixel circuits 3 is “blue-green-red”.

In some embodiments, as shown in FIG. 14, which is another schematic diagram of a display panel provided by embodiments of the present disclosure, the pixels 1 includes a first-type pixel 11 and a second-type pixel 12, and a distance between a pixel circuit 3 and its corresponding light-emitting element 4 in one first-type pixel 11 is greater than a distance between a pixel circuit 3 and its corresponding light-emitting element 4 in one second-type pixel 12.

At least in a same second-type pixel 12, the arrangement order of the multiple light-emitting elements 4 is the same as the arrangement order of the multiple pixel circuits 3, i.e., the arrangement order of the multiple colors corresponding to the multiple light-emitting elements 4 is the same as the arrangement order of the multiple colors corresponding to the multiple pixel circuits 3.

Exemplarily, in a second-type pixel 12, the first light-emitting element 4-1, the second light-emitting element 4-2, and the third light-emitting element 4-3 are arranged sequentially, and the first pixel circuit 3-1, the second pixel circuit 3-2, and the third pixel circuit 3-3 are arranged sequentially. In this case, both the arrangement orders of the multiple colors corresponding to the multiple light-emitting elements 4 and that corresponding to the multiple pixel circuits 3 are “red-green-blue”.

The second-type pixel 12 may be regarded as a conventional pixel in the display panel, the pixel circuits 3 and light-emitting elements 4 of this type of pixels are still arranged in the original arrangement order.

The first-type pixels 11 include a first pixel 13, and at least in a same first pixel 13, the arrangement order of the multiple light-emitting elements 4 is different from the arrangement order of the multiple pixel circuits 3, i.e., the arrangement order of the multiple colors corresponding to the multiple light-emitting elements 4 is different from the arrangement order of the multiple colors corresponding to the multiple pixel circuits 3.

Exemplarily, in a first pixel 13, the first light-emitting element 4-1, the second light-emitting element 4-2, and the third light-emitting element 4-3 are arranged sequentially, and in this case, the arrangement order of the multiple colors corresponding to the multiple light-emitting elements 4 is “red-green-blue”; the third pixel circuit 3-3, the second pixel circuit 3-2, and the first pixel circuit 3-1 are arranged sequentially, and in this case, the arrangement order of the multiple colors corresponding to the multiple pixel circuits 3 is “blue-green-red”.

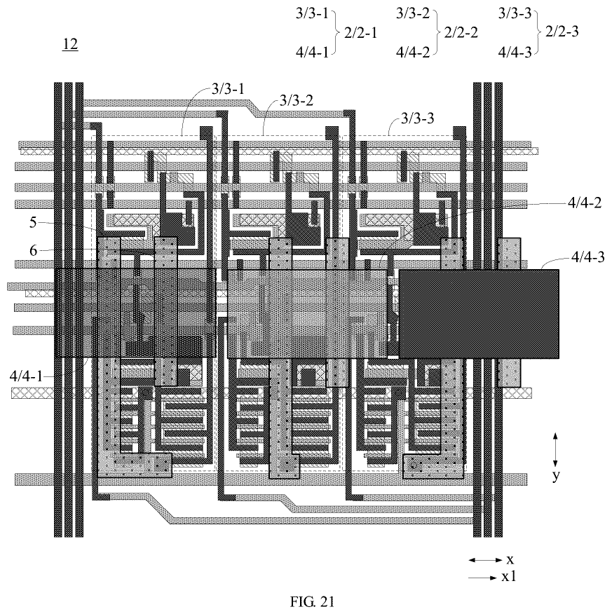

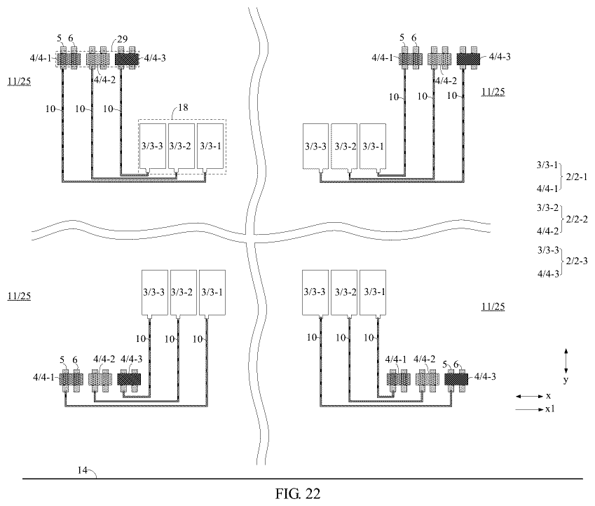

For the second-type pixels 12, since the pixel circuits 3 and their corresponding light-emitting elements 4 in the second-type pixels 12 are relatively close to each other, even if the pixel circuits 3 and light-emitting elements 4 in these pixels were still arranged in the conventional arrangement order, the connections between the pixel circuits 3 and their corresponding light-emitting elements 4 are simple. For instance, as shown in FIGS. 20 and 21, the pixel circuit 3 may be directly connected to its corresponding light-emitting element 4 through the first electrode 5 without connecting portions.

In the first pixel 13, since the pixel circuit 3 and its corresponding light-emitting element 4 in the first pixel 13 are relatively far away from each other, this pixel circuit 3 and the light-emitting element 4 are connected to each other via the first connecting portion 10. By adjusting the arrangement order of the pixel circuits 3 and/or light-emitting elements 4 in the first pixels 13, the design of the first connecting portions 10 corresponding to the first pixels 13 may become relatively flexible, allowing the first connecting portions 10 to avoid overlapping without wire winding as much as possible.

To further optimize the layout design of the first connecting portions 10 and ensure that the first connecting portions 10 corresponding to the first pixel 13 may overcome issues of overlapping without bypassing, as shown in FIG. 15, which is a schematic diagram of first pixels 13 provided by embodiments of the present disclosure, in at least one first pixel 13, the arrangement order of the multiple light-emitting elements 4 is opposite to the arrangement order of the multiple pixel circuits 3, i.e., the arrangement order of the multiple colors corresponding to the multiple light-emitting elements 4 is opposite to that corresponding to the multiple pixel circuits 3.

In some embodiments, as shown in FIG. 14, in different first pixels 13, the arrangement orders of the multiple light-emitting elements 4 are the same, and the arrangement orders of the multiple pixel circuits 3 are also the same, i.e., the arrangement orders of the multiple colors corresponding to the multiple light-emitting elements 4 are the same, and the arrangement orders of the multiple colors corresponding to the multiple pixel circuits 3 are also the same.

With such configuration, the arrangement orders of the light-emitting elements 4 and pixel circuits 3 in different first pixels 13 are designed uniformly, which allows the arrangement orders of the pixel circuits 3 and light-emitting elements 4 in the first pixels 13 more regular. For instance, referring to two first-type first pixels 25 shown in FIG. 14, the arrangement orders of the light-emitting elements 4 in these two first-type first pixels 25 are consistent, and the arrangement orders of the pixel circuits 3 in these two first-type first pixels 25 are consistent. When designing the first connecting portions 10 corresponding to these two first-type first pixels 25, the first connecting portions 10 of these two first-type first pixels 25 extend in a similar manner, thereby reducing difficulties in the layout design of the first connecting portions 10. Moreover, the light-emitting elements 4 in different first pixels 13 follow the same arrangement order, which may also reduce the display differences between different first pixels 13.

In some embodiments, as shown in FIG. 14, in the first pixels 13 and the second-type pixels 12, the arrangement orders of multiple light-emitting elements 4 are the same, i.e., the arrangement orders of multiple colors corresponding to the multiple light-emitting elements 4 are the same.

In some embodiments, the original arrangement order of the light-emitting elements 4 in the first pixels 13 does not change. Instead, it achieves different arrangement orders between the light-emitting elements 4 and the pixel circuits 3 only by changing the arrangement order of the pixel circuits 3 in the first pixels 13. Compared with simultaneously adjusting the arrangement orders of both the light-emitting elements 4 and the pixel circuits 3, this mode requires minimal modifications to the original structure of the first pixels 13 and reduces design complexity, while optimizing the arrangement of the first connecting portions 10.

During the manufacturing process of LED display panels, LEDs are first picked up from a growth substrate and then transferred to the driving backplate before being bonded with the first electrode 5 and the second electrode 6. Since, in the above setting mode, the original arrangement order of the light-emitting elements 4 in a first pixel 13 does not change, which will not affect the order of the light-emitting elements 4 grown on the growth substrate, pickup and transfer of the light-emitting elements 4.

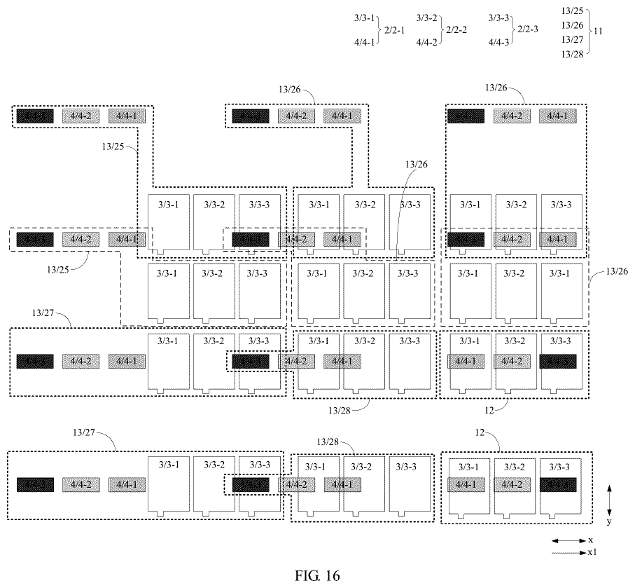

In other embodiments, as illustrated in FIG. 16, which is another schematic diagram of a display panel provided by embodiments of the present disclosure, in the first pixels 13 and the second-type pixels 12, the arrangement orders of multiple pixel circuits 3 are the same, i.e., the arrangement orders of multiple colors corresponding to the multiple pixel circuits 3 are the same.

The original arrangement order of the light-emitting elements 4 in the first pixels 13 does not change. Instead, it achieves different arrangement orders between the light-emitting elements 4 and the pixel circuits 3 only by changing the arrangement order of the light-emitting elements 4 in the first pixels 13. Compared with simultaneously adjusting the arrangement orders of both the light-emitting elements 4 and the pixel circuits 3, this mode requires minimal modifications to the original structure of the first pixels 13 and reduces design complexity, while achieving the purpose of optimizing the arrangement of the first connecting portions 10.

In some embodiments, in combination with FIGS. 17 and 22-29, the display panel includes a first outer edge 14 extending along the first direction x. The embodiments of the present disclosure are exemplified with the first outer edge 14 being the edge of the lower frame side of the display panel.

In the first pixel 13, the pixel circuit 3 is electrically connected to the light-emitting element 4 via the first connecting portion 10, the first connecting portion 10 is led out from a side of the pixel circuit 3 close to the first outer edge 14 and electrically connected to the light-emitting element 4 at a side of the light-emitting element 4 close to the same first outer edge 14. The first connecting portion 10 is connected to the light-emitting element 4 through the first electrode 5 at the side of the light-emitting element 4 close to the first outer edge 14, i.e., the first connecting portion 10 is connected to the first electrode 5 at a side of the first electrode 5 corresponding to the light-emitting element 4 close to the first outer edge 14.

In this structure, the first connecting portions 10 corresponding to different first pixels 13 are all led out from a same side of the pixel circuits 3, meaning that the output electrodes of these pixel circuits 3 are all designed on the same side. In this way, there is no need for additional adjustments for the output electrodes of different pixel circuits 3, enabling a consistent layout design for these pixel circuits 3, thus simplifying the layout design. Similarly, the first connecting portions 10 corresponding to different first pixels 13 are all electrically connected to the light-emitting elements 4 (first electrodes 5) at the same side of the light-emitting elements 4 (first electrodes 5), and thus when designing connection via holes between the first electrode 5 and the first connection portion 10, the connection via holes are also located at a same side of the first electrodes 5, the connection via holes are uniformly located, which may simplify the layout design.

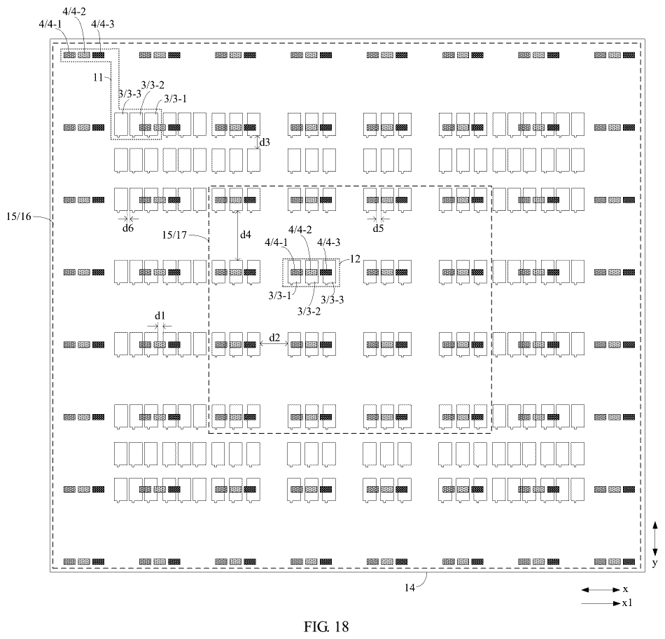

FIG. 17 shows another schematic diagram of a display panel provided by embodiments of the present disclosure, and FIG. 18 shows another structure schematic diagram of a display panel provided by embodiments of the present disclosure. In some embodiments, as shown in FIGS. 17 and 18, the display panel has a display region 15, the display region 15 includes a first region 16 and a second region 17, and the first region 16 is located at a side of the second region 17 close to an edge of the display panel. That is, the first region 16 is an edge display region close to the outer edge of the display panel, and the second region 17 is a middle display region.

The first-type pixels 11 are located in the first region 16, and the second-type pixels 12 are located in the second region 17. In some embodiments, along the first direction x and/or the second direction y, a spacing between at least two adjacent pixel circuits 3 in the first-type pixels 11 is smaller than a spacing between adjacent pixel circuits 3 in the second-type pixels 12, and the second direction y intersects the first direction x.

In some embodiments, “along the first direction x and/or the second direction y, a spacing between at least two adjacent pixel circuits 3 in the first-type pixels 11 is smaller than a spacing between adjacent pixel circuits 3 in the second-type pixels 12” may include following cases: referring to FIGS. 17 and 18, the spacing d1 between at least two adjacent pixel circuits 3 in the first-type pixels 11 along the first direction x is smaller than the spacing d2 between at least two adjacent pixel circuits 3 in the second-type pixels 12 along the first direction x; and/or, referring to FIGS. 17 and 18, the spacing d3 between at least two adjacent pixel circuits 3 in the first-type pixels 11 along the second direction y is smaller than the spacing d4 between at least two adjacent pixel circuits 3 in the second-type pixels 12 along the second direction y; and/or, referring to FIG. 18, the spacing d5 between two adjacent pixel circuits 3 in at least one first-type pixel 11 is smaller than the spacing d6 between two adjacent pixel circuits 3 in at least one second-type pixel 12.

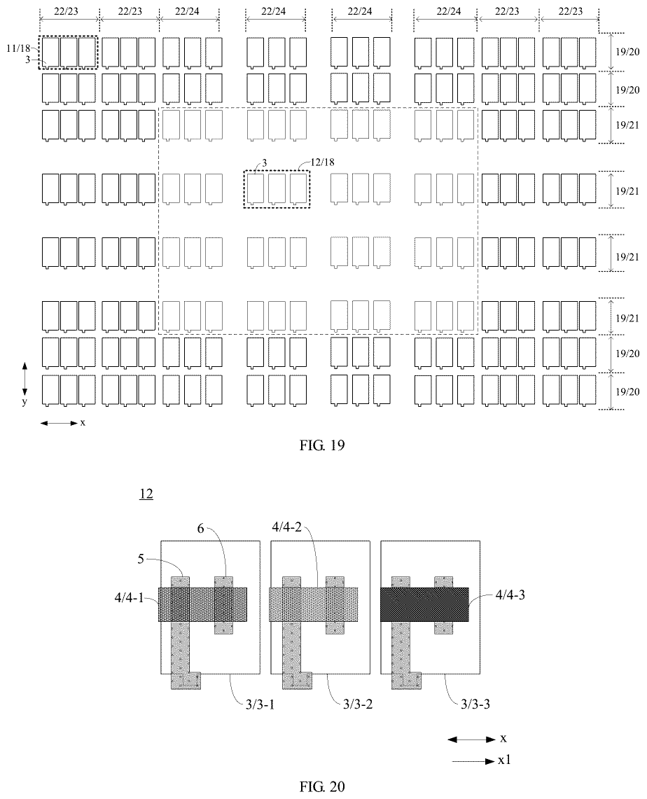

FIG. 19 is another schematic diagram of a display panel according to embodiments of the present disclosure. In some embodiments, as shown in FIG. 19, multiple pixel circuits 3 in a pixel 1 form a circuit unit 18. The display region 15 includes multiple circuit rows 19 arranged along the second direction y, with each circuit row 19 including multiple circuit units 18 arranged along the first direction x. The multiple circuit rows include a first circuit row 20 and a second circuit row 21, with the first circuit row 20 located at at least one side of the second circuit row 21 along the second direction y, i.e., the first circuit rows 20 is closer to the outer edge of the display panel. A distance between adjacent first circuit rows 20 is smaller than a distance between adjacent second circuit rows 21.

The display region 15 also includes multiple circuit columns 22 arranged along the first direction x, with the circuit column 22 including multiple circuit units 18 arranged along the second direction y. The multiple circuit columns 22 include a first circuit column 23 and a second circuit column 24, with the first circuit column 23 located at at least one side of the second circuit column 24 along the first direction x, i.e., the first circuit column 23 is closer to the outer edge of the display panel. A distance between adjacent first circuit columns 23 is smaller than a distance between adjacent second circuit columns 24, and/or a spacing between two adjacent pixel circuits 3 in the circuit unit 18 in the first circuit column 23 is smaller than a spacing between two adjacent pixel circuits 3 in the circuit unit 18 in the second circuit column 24.

The pixel circuits 3 of the first-type pixels 11 are located in the first circuit row 20 and the first circuit column 23, and the pixel circuits 3 of the second-type pixels 12 are located in the second circuit row 21 and the second circuit column 24.

The above structure achieve an inward retraction design of pixel circuits 3 near the edges of the display panel towards the second region 17, which increases the distances between these pixel circuits 3 and the outer edge of the display panel. As a result, when the edges of the display panel are cut using the laser cutting process, the risk of transistor failure in these pixel circuits 3 may be reduced.

Such configuration is suitable for a narrow-bezel or a bezel-less display panels whose bezel has a small width. The cutting edges of the display panels are closer to the pixel circuits 3 at the edge. By adopting the above design, the issue of transistor failure caused by cutting in such display panels may be mitigated.

In some embodiments, referring to FIG. 17, in a direction perpendicular to a plane of the display panel, at least one pixel circuit 3 in the first-type pixels 11 does not overlap with at least one light-emitting element 4 corresponding to the at least one pixel circuit 3, and the at least one light-emitting element 4 is closer to the outer edge of the display panel than the at least one pixel circuit 3, which leads the at least one pixel circuit 3 away from the outer edge of the display panel, thereby reducing the risk of transistor failure caused by the cutting process.

In the direction perpendicular to the plane of the display panel, the pixel circuit 3 in the second-type pixels 12 overlaps with its corresponding light-emitting element 4. FIG. 20 is a schematic diagram of the second-type pixels 12 provided by embodiments of the present disclosure, and FIG. 21 is a schematic diagram of a layer structure of the second-type pixels 12 provided by embodiments of the present disclosure. As shown in FIGS. 20 and 21, the pixel circuit 3 in the second-type pixel 12 and its corresponding light-emitting element 4 are very close to each other, and this pixel circuit 3 may be connected to the light-emitting element 4 merely through the first electrode 5.

In some embodiments, the relative position relationship between the pixel circuits 3 and the light-emitting elements 4 in the first-type pixel 11 varies with different positions, and correspondingly, the arrangement methods of the first connecting portions 10 are also different at different positions. The following provides a detailed illustration of the arrangement methods of the first connecting portions 10 corresponding to different first pixels 13.

In the pixel 1, multiple light-emitting elements 4 form a light-emitting unit 29, and multiple pixel circuits 3 form a circuit unit 18.

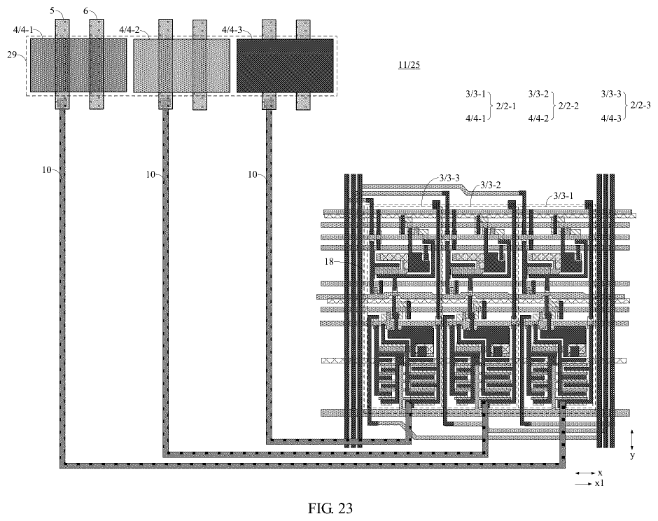

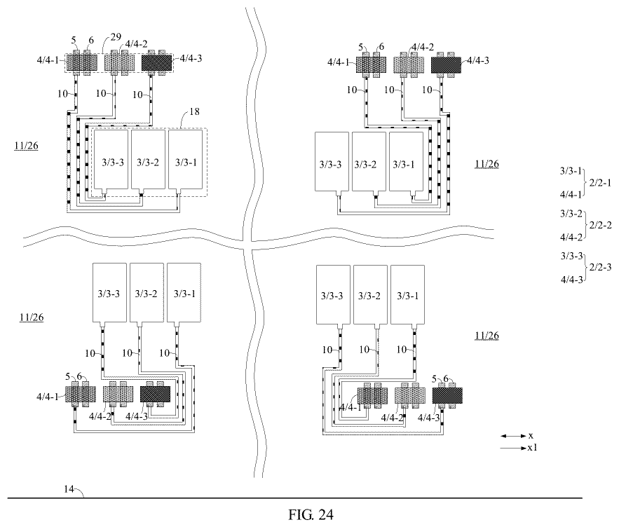

FIG. 22 is a schematic diagram of the first-type first pixels 25 provided by embodiments of the present disclosure, and FIG. 23 is a schematic diagram of a layer structure of the first-type first pixels 25 provided by embodiments of the present disclosure. In some embodiments, in combination with FIGS. 16, 17, 22, and 23, the first pixels 13 include a first-type first pixel 25.

In the first-type first pixel 25, an orthogonal projection of a light-emitting unit 29 on the plane of the display panel and an orthogonal projections of a circuit unit 18 on the plane of the display panel do not overlap in neither the first direction x nor the second direction y, which intersects the first direction x. In the first-type first pixel 25, the arrangement order of multiple light-emitting elements 4 is opposite to the arrangement order of multiple pixel circuits 3, i.e., the arrangement order of multiple colors corresponding to the multiple light-emitting elements 4 is opposite to the arrangement order of multiple colors corresponding to the multiple pixel circuits 3.

In combination with FIG. 17, four first-type first pixels 25 illustrated in FIG. 22 may be regarded as the first-type first pixels 25 located at the four top corners of the display panel.

Referring to the upper tw first-type first pixels 25 in FIG. 22, in at least one first-type first pixel 25, the distance between a circuit unit 18 and the first outer edge 14 is smaller than the distance between a light-emitting unit 29 and the first outer edge, and at least one first connecting portion 10 corresponding to the at least one first-type first pixel 25 is led out from the side of at least one pixel circuit 3 close to the first outer edge 14, and then extends from the side of the circuit unit 18 close to the light-emitting unit 29 in the first direction x to the side of the at least one light-emitting element 4 close to the same first outer edge 14, to be electrically connected to the at least one light-emitting element 4.

In some embodiments, referring to the lower two first-type first pixels 25 in FIG. 22, in at least one first-type first pixel 25, the distance between a circuit unit 18 and the first outer edge 14 is greater than the distance between the light-emitting unit 29 and the first outer edge 14, and at least one first connecting portion 10 corresponding to the at least one first-type first pixel 25 is led out from the side of the pixel circuit 3 close to the first outer edge 14, and then extends from the side of the light-emitting unit 29 close to the circuit unit 18 in the first direction x to the side of the at least one light-emitting element 4 close to the first outer edge 14, to be electrically connected to the at least one light-emitting element 4.

Compared with FIGS. 2 and 4 in related technologies, for the first-type first pixel 25 where the light-emitting unit 29 and the circuit unit 18 do not overlap in neither the first direction x nor the second direction y, based on the above configuration, the multiple first connecting portions 10 corresponding to the at least one first-type first pixel 25 do not overlap without bypassing, resulting in a more optimized layer design for the first connecting portions 10.

When the light-emitting units 29 and the circuit units 18 do not overlap in neither the first direction x nor the second direction y, taking the first-type first pixel 25 where the circuit unit 18 is closer to the first outer edge 14 as an example, by allowing the first connecting portions 10 corresponding to the first-type first pixel 25 to extend from the side of the circuit unit 18 close to the light-emitting unit 29 in the first direction x, the wiring length of the first connecting portions 10 can be reduced, which not only reduces the arrangement space of the first connecting portions 10 to minimize position conflicts with other lines in the same layer, but also reduces their load.

In the above configuration, the first connecting portions 10 corresponding to different first-type first pixels 25 are all led out from the same side of the pixel circuits 3 and are all electrically connected to the light-emitting elements 4 (first electrodes 5) at the same side of the light-emitting elements 4 (first electrodes 5). In this way, the output electrodes of the pixel circuits 3 in the first-type first pixels 25 can be designed at the same side, and the connection via holes between the first electrodes 5 and the first connecting portions 10 corresponding to the first-type first pixels 25 may also be designed at the same side of the first electrodes 5, simplifying the layout design.

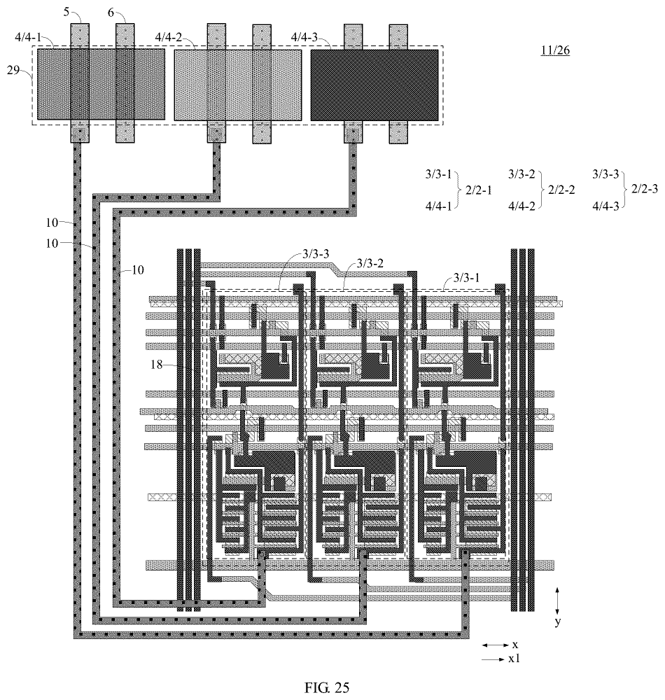

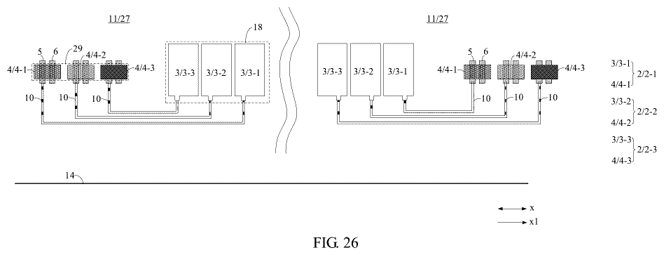

FIG. 24 illustrates a schematic diagram of second-type first pixels 26 provided by embodiments of the present disclosure, and FIG. 25 illustrates schematic diagram of a layer structure of the second-type first pixels 26 provided by embodiments of the present disclosure. In some embodiments, in combination with FIGS. 16, 17, 24, and 25, the first pixels 13 includes a second-type first pixel 26.

In the second-type first pixel 26, an orthographic projections of a light-emitting unit 29 on the plane of the display panel and an orthographic projections of a circuit unit 18 on the plane of the display panel do not overlap in the first direction x, but overlap in the second direction y, and at least one orthographic projection of at least one pixel circuits 3 on the plane of the display panel and at least one orthographic projection of at least one light-emitting element 4 on the plane of the display panel do not overlap. The second direction y intersects with the first direction x. In the second-type first pixel 26, the arrangement order of multiple light-emitting elements 4 is opposite to the arrangement order of multiple pixel circuits 3, i.e., the arrangement order of multiple colors corresponding to the multiple light-emitting elements 4 is opposite to the arrangement order of multiple colors corresponding to the multiple pixel circuits 3.

In Combination with FIG. 17, four second types of first pixels 26 illustrated in FIG. 24 may be regarded as the second-type first pixels 26 located at four top corners of the display panel, respectively.

Referring to the upper two second-type first pixels 26 in FIG. 24, in at least one second-type first pixel 26, the distance between a circuit unit 18 and the first outer edge 14 is smaller than the distance between a light-emitting unit 29 and the first outer edge 14, and the at least one first connecting portion 10 corresponding to the at least one second-type first pixel 26 is led out from the side of at least one pixel circuit 3 close to the first outer edge 14, and extends from one side of the circuit unit 18 in the first direction x to the side of at least one light-emitting element 4 close to the first outer edge 14, to be electrically connected to the at least one light-emitting element 4.

In some embodiments, referring to the lower two second-type first pixels 26 in FIG. 24, in at least one second-type first pixel 26, the distance between a circuit unit 18 and the first outer edge 14 is greater than the distance between a light-emitting unit 29 and the first outer edge 14, and at least one first connecting portion 10 corresponding to the at least one second-type first pixel 26 is led out from the side of at least one pixel circuit 3 close to the first outer edge 14, and extends from one side of the light-emitting unit 29 in the first direction x to the side of the at least one light-emitting element 4 close to the first outer edge 14, to be electrically connected to the at least one light-emitting element 4.

Compared with FIGS. 3 and 5 in related technologies, for the second-type first pixel 26 where the light-emitting unit 29 and the circuit unit 18 overlap in the first direction x but does not overlap in the second direction y, based on the above configuration, the multiple first connecting portions 10 corresponding to the second-type first pixel 26 do not overlap without complex bypassing, resulting in a more optimized layer design for the first connecting portion 10.

Based on the above configuration, in this type of pixels, although the light-emitting unit 29 overlaps with the circuit unit 18 in the second direction y, the corresponding first connecting portion 10 extends from a side of the circuit unit 18 or the light-emitting unit 29 to the light-emitting element 4, which may avoid overlapping between the first connecting portion 10 and the pixel circuit 3, thereby reducing crosstalk between signals transmitted by the first connecting portion 10 and internal lines of the pixel circuit 3.

In the above configuration, the first connecting portions 10 corresponding to different second-type first pixels 26 are all led out from the same side of the pixel circuits 3 and are electrically connected to the light-emitting elements 4 (first electrodes 5) at a same side of the light-emitting elements 4 (first electrodes 5). In this way, the output electrodes of the pixel circuits 3 in the second-type first pixels 26 are designed at a same side, and the connection via holds between the first electrodes 5 and the first connecting portions 10 corresponding to the second-type first pixels 26 may also be designed at the same side of the first electrodes 5, simplifying the layout design.

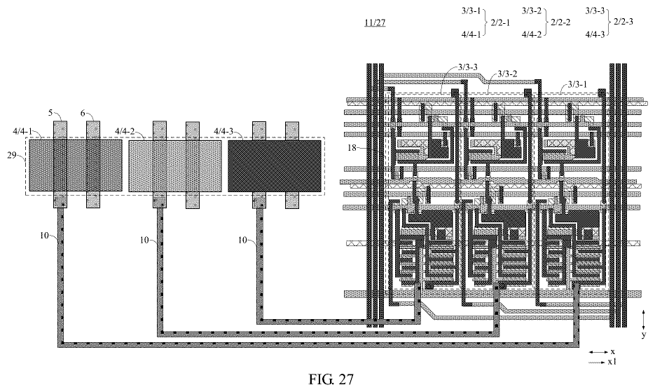

FIG. 26 illustrates a schematic diagram of third-type first pixels 27 provided by embodiments of the present disclosure, and FIG. 27 illustrates a schematic diagram of a layer structure of the third-type first pixels 27 provided by embodiments of the present disclosure. In some embodiments, in combination with FIGS. 16, 17, 26, and 27, the first pixels 13 include a third-type first pixel 27.

In the third-type first pixel 27, a light-emitting unit 29 and a circuit unit 18 are arranged along the first direction x. In the third-type first pixel 27, the arrangement order of multiple light-emitting elements 4 is opposite to the arrangement order of multiple pixel circuits 3, i.e., the arrangement order of multiple colors corresponding to the multiple light-emitting elements 4 is opposite to the arrangement order of multiple colors corresponding to the multiple pixel circuits 3.

The first connecting portions 10 corresponding to the third-type first pixel 27 are led out from the side of the pixel circuits 3 close to the first outer edge 14 and extend to the side of the light-emitting elements 4 close to the first outer edge 14, to be electrically connected to the light-emitting elements 4.

Combining with FIG. 17, two third-type first pixels 27 illustrated in FIG. 26 may be regarded as the third-type first pixels 27 close to the first edge 7 and the second edge 8, respectively.

For the third-type first pixels 27 where the light-emitting units 29 and the circuit units 18 are arranged along the first direction x, with the above configuration, it may achieve that the multiple first connecting portions 10 corresponding to the third-type first pixels 27 do not overlap without complex bypassing, resulting in an optimized layer design for the first connecting portions 10. In the above configuration, the first connecting portions 10 corresponding to different third-type first pixels 27 are all led out from the same side of the pixel circuits 3 and are also electrically connected to the light-emitting elements 4 (first electrodes 5) at the same side of the light-emitting elements 4 (first electrodes 5), which may not only simplify the layout design, but also reduce the extension length of the first connecting portions 10 and their load.

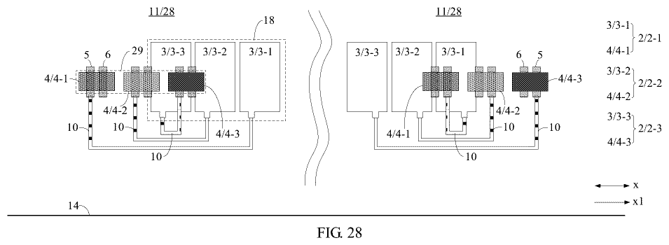

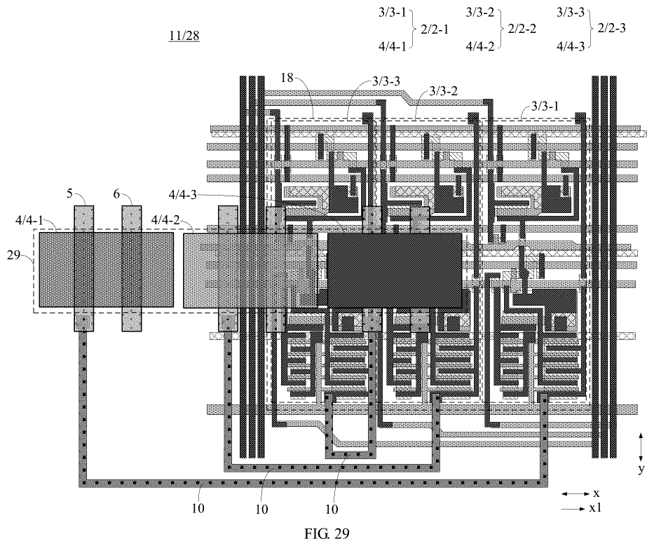

FIG. 28 illustrates a schematic diagram of fourth-type first pixels 28 provided by embodiments of the present disclosure, and FIG. 29 illustrates a schematic diagram of a layer structure of the fourth-type first pixels 28 provided by embodiments of the present disclosure. In some embodiments, in combination with FIGS. 16, 17, 28, and 29, the first pixels 13 include a fourth-type first pixel 28.

In the fourth-type first pixel 28, in the direction perpendicular to the plane of the display panel, a light-emitting unit 29 overlaps with a circuit unit 18, and at least one pixel circuit 3 and at least one light-emitting element 4 corresponding to the at least one pixel circuit 3 do not overlap. In the fourth-type first pixel 28, the arrangement order of multiple light-emitting elements 4 is opposite to the arrangement order of multiple pixel circuits 3, i.e., the arrangement order of multiple colors corresponding to the multiple light-emitting elements 4 is opposite to the arrangement order of multiple colors corresponding to the multiple pixel circuits 3.

The first connecting portions 10 corresponding to the fourth-type first pixel 28 are led out from the side of the pixel circuits 3 close to the first outer edge 14 and extend to the side of the light-emitting elements 4 close to the first outer edge 14, to be electrically connected to the light-emitting elements 4.

In combination with FIG. 17, two fourth-type first pixels 28 illustrated in FIG. 28 may be regarded as the fourth-type first pixels 28 close to the first edge 7 and the second edge 8, respectively.

For the fourth-type first pixels 28 where the light-emitting units 29 overlap with the circuit units 18, with the above configuration, it may achieve that the multiple first connecting portions 10 corresponding to the fourth-type first pixels 28 do not overlap without complex bypassing, resulting in an optimized layer design for the first connecting portions 10. In the above configuration, the first connecting portions 10 corresponding to different fourth-type first pixels 28 are all led out from the same side of the pixel circuits 3 and are also electrically connected to the light-emitting elements 4 (first electrodes 5) at the same side of the light-emitting elements 4 (first electrodes 5), which may not only simplify the layout design, but also reduce the extension length of the first connecting portions 10 and their load.

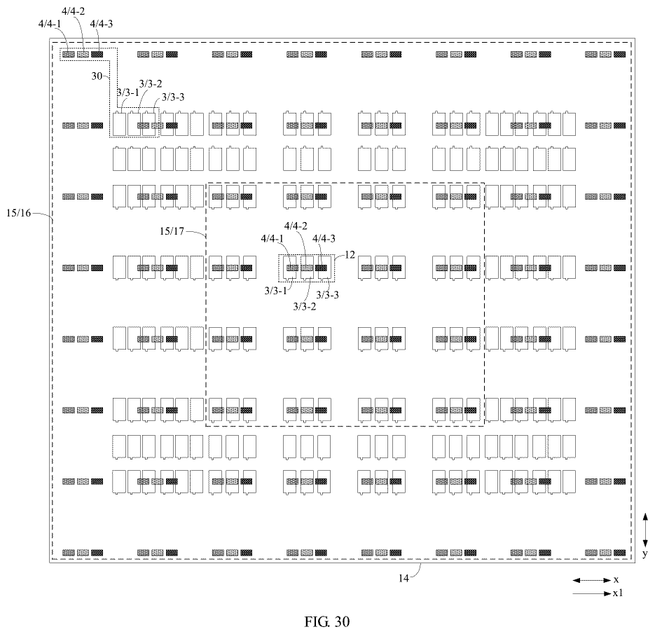

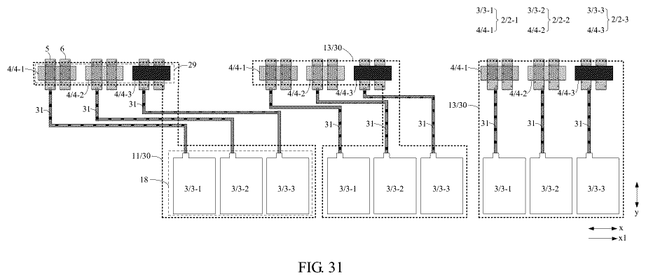

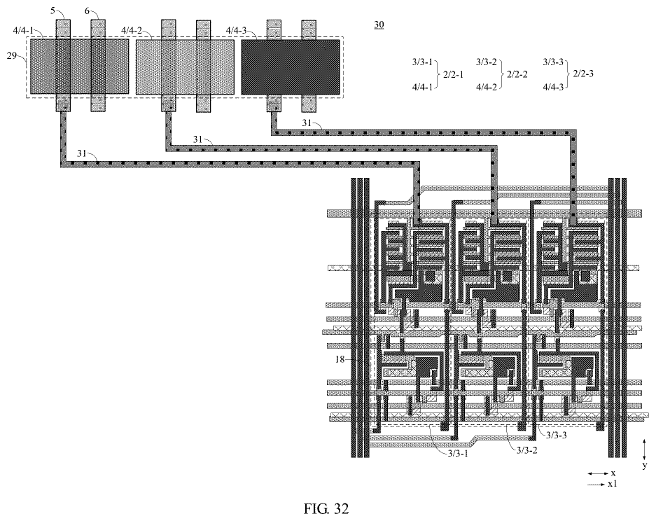

FIG. 30 illustrates another structural diagram of a display panel provided by embodiments of the present disclosure, FIG. 31 illustrates a schematic diagram of second pixels 30 provided by embodiments of the present disclosure, and FIG. 32 illustrates a schematic diagram of a layer structure of the second pixels 30 provided by embodiments of the present disclosure. In some embodiments, as shown in FIGS. 30 to 32, the first-type pixels 11 include a second pixel 30.

In at least one second pixel 30, an orthogonal projections of a light-emitting unit 29 on the plane of the display panel and an orthogonal projections of a circuit unit 18 on the plane of the display panel do not overlap in the first direction x. In a same second pixel 30, the arrangement order of the multiple light-emitting elements 4 is the same as the arrangement order of the multiple pixel circuits 3, i.e., the arrangement order of the multiple colors corresponding to the multiple light-emitting elements 4 is the same as the arrangement order of the multiple colors corresponding to the multiple pixel circuits 3.

In the second pixels 30, the pixel circuits 3 are electrically connected to the light-emitting elements 4 through second connecting portions 31. The second connecting portions 31 are led out from the side of the pixel circuits 3 close to the light-emitting unit 29 in the second direction y and electrically connected to the light-emitting elements 4 at the side of the light-emitting elements 4 close to the circuit unit 18 in the second direction y, which intersects with the first direction x.

For the pixels where the light-emitting units 29 and the circuit units 18 do not overlap in the first direction x, the output electrodes of the pixel circuits 3 in at least one pixels may be reversed, so that the at least one pixel circuit 3 is led out from the side close to the light-emitting unit 29 in the second direction y. Such configuration allows the second connecting portions 31 to avoid each other without complex bypassing and without changing the arrangement orders of the pixel circuits 3 and the light-emitting elements 4.

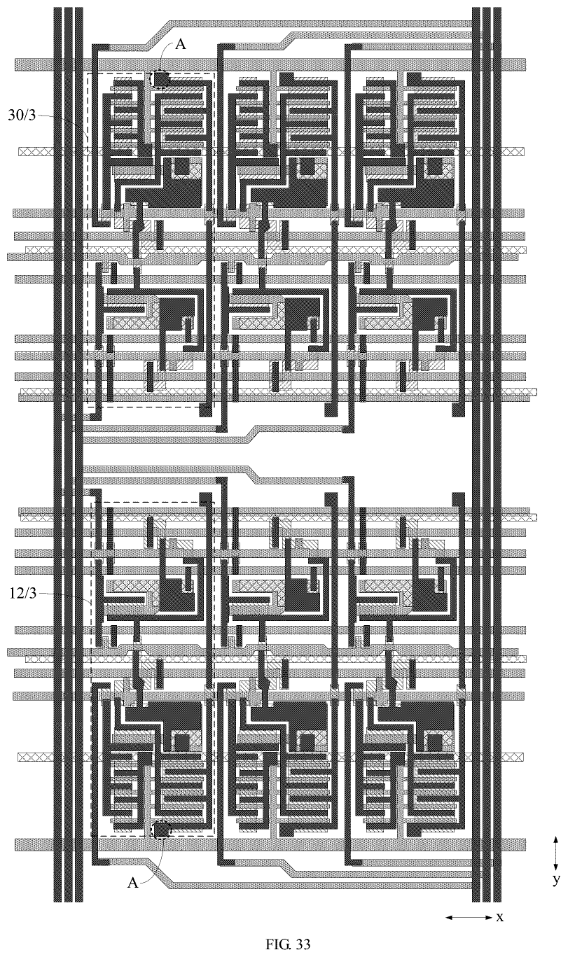

In some embodiments, as shown in FIG. 33, which illustrates a schematic diagram of a layer structure of a display panel provided by embodiments of the present disclosure, the patterns of the pixel circuits 3 in at least one second pixel 30 after flipping with the first direction x as the axis are the same as the patterns of the pixel circuits 3 in the second-type pixels 12. For example, the patterns of the pixel circuits 3 in at least one second pixel 30 after rotating 180° on the plane of the display panel with the first direction x as the axis are the same as the patterns of the pixel circuits 3 in the second-type pixel 12.

In such configuration, the patterns of the pixel circuits 3 in at least one second pixel 30 is flipped to move the output electrodes A of the pixel circuits 3 electrically connected to the first connecting portions 10 to the side close to the light-emitting units 29 in the second direction y. In this way, the pattern designs of the pixel circuits 3 in the second pixels 30 and the pattern designs of the second-type pixels 12 remain the same, simplifying the layout design.

In some embodiments, referring to FIG. 30, in the second pixels 30, the side of the pixel circuits 3 close to the light-emitting units 29 in the second direction y is the side of the pixel circuits 3 close to the edge of the display panel in the second direction y, thereby achieving an inward retraction design for these pixel circuits 3.

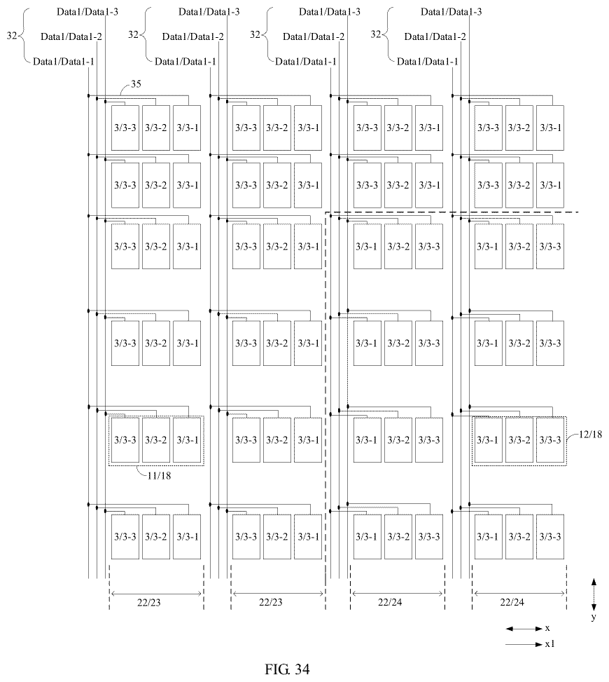

In some embodiments, as shown in FIG. 34, which illustrates another schematic diagram of a display panel provided by embodiments of the present disclosure, multiple pixel circuits 3 in a pixel 1 form a circuit unit 18, and multiple circuit units 18 arranged along the second direction y form a circuit column 22, where the second direction y intersects with the first direction x.

The display panel can include multiple first data line groups 32, one first data line group 32 corresponds to one circuit column 22, and a first data line group 32 is located at a side of the corresponding circuit column 22 in the first direction x. A first data line group 32 includes multiple first data lines Data1 arranged along the first direction x, and multiple pixel circuits 3 in each circuit unit 18 in a circuit column 22 are electrically connected to the multiple first data lines Data1 of the corresponding first data line group 32, respectively.

A spacing between two adjacent circuit units 18 is greater than a distance between two adjacent pixel circuits 3 within a circuit unit 18. Therefore, by placing the first data line group 32 at a side of the circuit unit 18 in the first direction x, it is possible to make rational use of the space between adjacent circuit units 18, which avoids that the first data lines Data occupy the space between two adjacent pixel circuits 3 in the circuit units 18, and avoids that the arrangement of other lines in the same layer within that space is affected.

In some embodiments, referring to FIG. 34 again, the same first data line Data1 is electrically connected to the pixel circuits 3 in subpixels 2 of a same color. The arrangement order of multiple first data lines Data1 in a first data line group 32 is the same as the arrangement order of multiple pixel circuits 3 in a second-type pixel 12.

Since the same first data line Data1 is electrically connected to the pixel circuits 3 in the subpixels 2 of a same color, each first data line Data1 also corresponds to a color, and the color corresponding to a first data line Data1 is the same as the color corresponding to a pixel circuit 3 connected to the first data line Data1. Therefore, the arrangement order of multiple first data lines Data1 in the first data line group 32 may also be represented by the arrangement order of colors.

As an example, referring to FIG. 34, the multiple first data lines Data1 in the first data line group 32 include a first data sub-line Data1-1, a second data sub-line Data1-2, and a third data sub-line Data1-3. The first data sub-line Data1-1 is electrically connected to the first pixel circuit 3-1, corresponding to the red color, the second data sub-line Data1-2 is electrically connected to the second pixel circuit 3-2, corresponding to the green color, and the third data sub-line Data1-3 is electrically connected to the third pixel circuit 3-3, corresponding to the blue color.

In the second-type pixel 12, the first pixel circuit 3-1, the second pixel circuit 3-2, and the third pixel circuit 3-3 are arranged sequentially, with their corresponding colors arranged in the order of “red-green-blue”. In the first data line group 32, the first data sub-line Data1-1, the second data sub-line Data1-2, and the third data sub-line Data1-3 are arranged sequentially, with their corresponding colors also arranged in the order of “red-green-blue”.

That is, “the arrangement order of multiple first data lines Data1 in the first data line group 32 is the same as the arrangement order of multiple pixel circuits 3 in the second-type pixel 12” may also be expressed as “the arrangement order of multiple colors corresponding to the multiple first data lines Data1 in the first data line group 32 is the same as the arrangement order of multiple colors corresponding to the multiple pixel circuits 3 in the second-type pixel 12, where the color of the first data line Data1 corresponds to the color of the pixel circuit 3 connected to the first data line Data1”.

With such configuration, the arrangement orders of the multiple first data lines Data1 in different first data line groups 32 are consistent, and the connection orders of multiple first data lines Data1 in different first data line groups 32 to the original interfaces in a driver chip are also consistent, without matching different interface orders for different first data line groups 32.

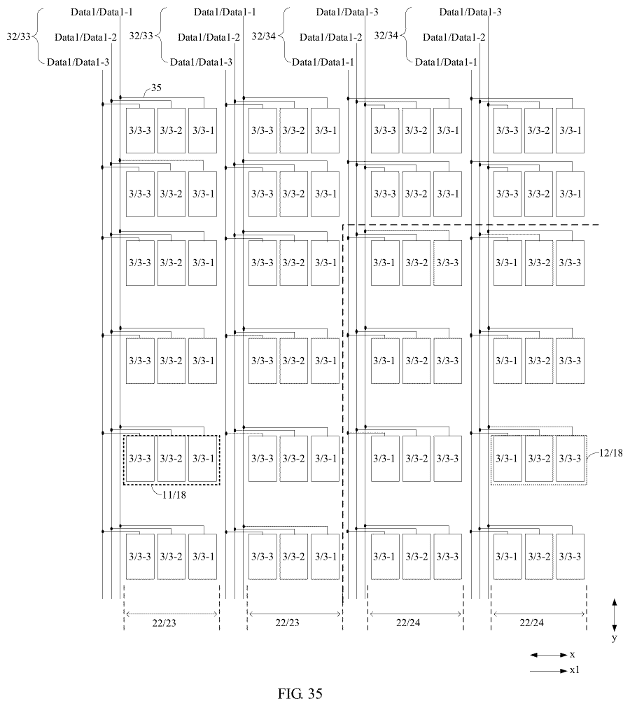

In some embodiments, in combination with FIG. 19, as shown in FIG. 35, which illustrates another schematic diagram of a display panel provided by embodiments of the present disclosure, the circuit columns 22 include a first circuit column 23 and a second circuit column 24.

A same first data line Data1 is electrically connected to the pixel circuits 3 in the subpixels 2 of a same color.

The first data line groups 32 include a first-type first data line group 33 electrically connected to the first circuit column 23 and a second-type first data line group 34 electrically connected to the second circuit column 24.

The arrangement order of multiple first data lines Data1 in the first-type first data line groups 33 differs from the arrangement order of multiple first data lines Data1 in the second-type first data line groups 34. In view of the previous analysis, the arrangement order of multiple colors corresponding to multiple first data lines Data1 in the first-type first data line groups 33 differs from the arrangement order of multiple colors corresponding to multiple first data lines Data1 in the second-type first data line groups 34, where the color of the first data line Data1 corresponds to the color of the pixel circuit 3 connected to the first data line Data1.

This structure provides greater flexibility in designing the arrangement order of the first data lines Data1 in the first data line group 32, which facilitates to optimize the arrangement of the first connecting lines 35 between the pixel circuits 3 in different circuit columns 22 and the first data lines Data1.

For example, referring to FIG. 35 again, the arrangement order of multiple pixel circuits 3 in a first pixel 13 differs from the arrangement order of multiple pixel circuits 3 in a second-type pixel 12. In some embodiments, the arrangement orders of multiple pixel circuits 3 in different first pixels 13 may be the same.

The first circuit columns 23 include the pixel circuits 3 in the first pixels 13, and for example, the first circuit columns 23 merely include the pixel circuits 3 in the first pixels 13. The second circuit columns 24 include at least the pixel circuits 3 in the second-type pixels 12, and for example, the second circuit columns 24 may also include pixel circuits 3 in both the first pixel 13 and the second-type pixel 12.

The arrangement order of multiple first data lines Data1 in the first-type first data line group 33 is the same as the arrangement order of multiple pixel circuits 3 in the first pixel 13. In other words, the arrangement order of multiple colors corresponding to multiple first data lines Data1 in the first-type first data line group 33 is the same as the arrangement order of multiple colors corresponding to multiple pixel circuits 3 in the first pixel 13.

The arrangement order of multiple first data lines Data1 in the second-type first data line groups 34 is the same as the arrangement order of multiple pixel circuits 3 in the second-type pixel 12, that is, the arrangement order of multiple colors corresponding to multiple first data lines Data1 in the second-type first data line groups 34 is the same as the arrangement order of multiple colors corresponding to multiple pixel circuits 3 in the second-type pixel 12.

After adjusting the arrangement order of pixel circuits 3 in the first pixels 13, the arrangement order of multiple first data lines Data1 in the first-type first data line group 33 is adjusted to be same as the arrangement order of pixel circuits 3 in the first pixels 13, so that the wiring method of the first connecting lines 35 between the pixel circuits 3 in the first pixels 13 and the first data lines Data1 in the first-type first data line groups 33 is the same as the wiring method of the first connecting lines 35 between the pixel circuits 3 in the second-type pixels 12 and the first data lines Data1 in the second-type first data line groups 34, simplifying the layout design of these first connecting lines 35.

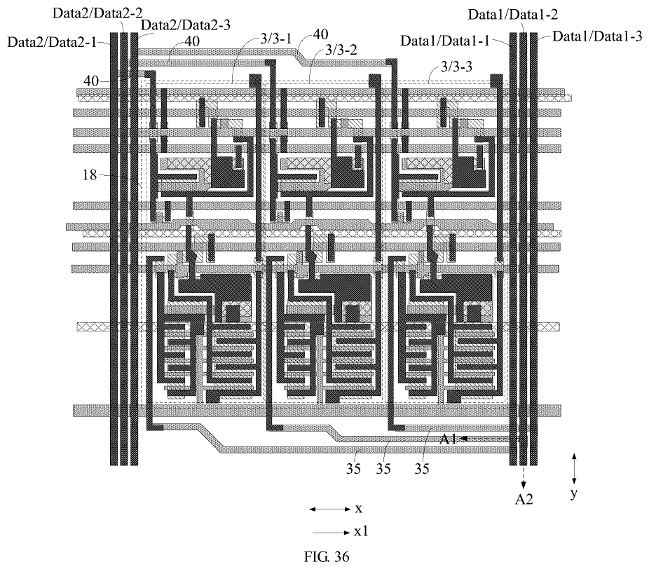

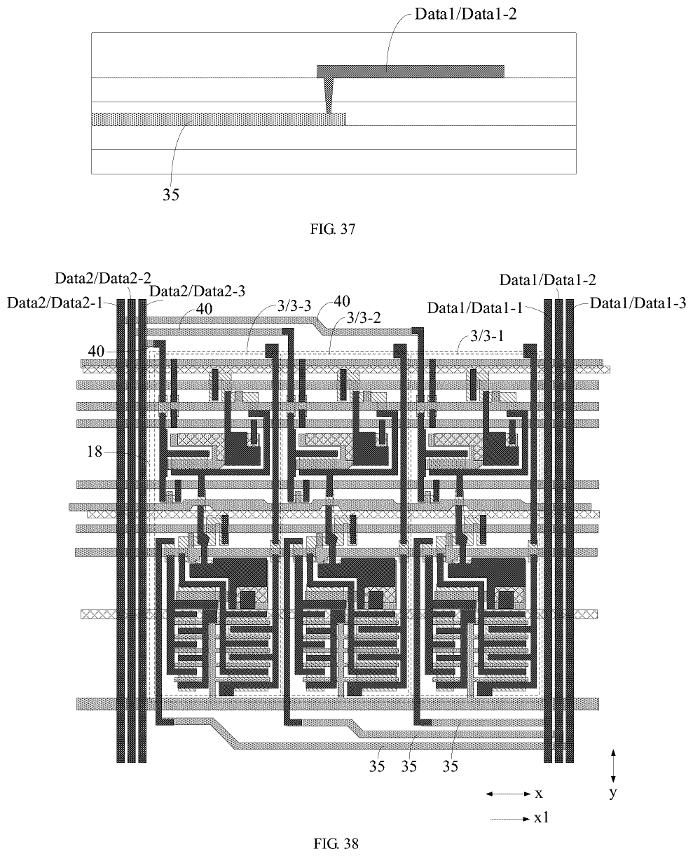

FIG. 36 illustrates a schematic diagram of a layer structure of a display panel provided by embodiments of the present disclosure, and FIG. 37 is a cross-sectional view of FIG. 36 along line A1-A2. In some embodiments, as shown in FIGS. 36 and 37, the pixel circuit 3 is electrically connected to the first data line Data1 through the first connecting line 35, the first data line Data1 is located at a side of the pixel circuit 3 in the second direction y, and the first connecting line 35 is arranged in a different layer from the first data line Data1. In this way, a short circuit will not occur between the first connecting line 35 and other first data lines Data1 when the first connecting line 35 is connected to the first data line Data1 corresponding to the first connecting line 35.

FIG. 38 illustrates another schematic diagram of a layer structure of a display panel provided by embodiments of the present disclosure. In some embodiments, referring to FIGS. 36 and 38, For the pixel 1 and the first data line group 32 that are connected to each other, regardless of whether the arrangement order of multiple colors corresponding to multiple pixel circuits 3 in the pixels 1 is the same as or different from the arrangement order of multiple colors corresponding to multiple first data lines Data1 in the first data line group 32, there will be no position conflicts among multiple first connecting lines 35 when the pixel circuit 3 is connected to its corresponding first data line Data1 via the first connecting line 35, achieving flexible arrangement of the first connecting lines 35.

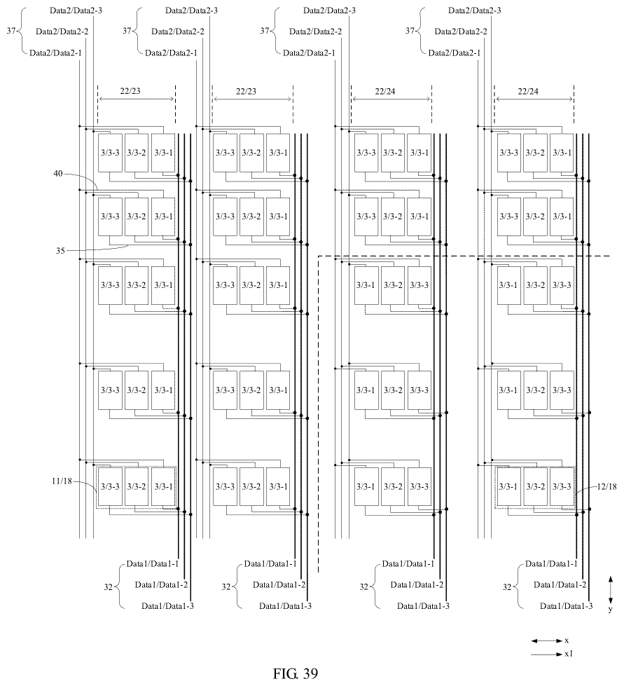

In some embodiments, as shown in FIG. 39, which illustrates another schematic diagram of a display panel provided by embodiments of the present disclosure, the display panel includes multiple second data line groups 37, one second data line group 37 corresponding to one circuit column 22, the second data line group 37 includes multiple second data lines Data2 arranged along the first direction x, and the multiple pixel circuits 3 in the circuit unit 18 in the circuit column 22 are electrically connected to the multiple second data lines Data2 in the second data line group 37 corresponding to these pixel circuits 3, respectively.

For the first data line group 32 and the second data line group 37 that are connected to a same circuit column 22, the first data line group 32 and the second data line group 37 are located at opposite sides of the circuit column 22, and the first data line groups 32 and the second data line groups 37 are alternately arranged in the first direction x.

On one hand, placing the second data line groups 37 at a side of the circuit column 22 may avoid that the second data lines Data2 occupy the space between two adjacent pixel circuits 3 in a circuit unit 18, and avoid that the arrangement of other lines in the same layer within that space is affected. On the other hand, with the first data line group 32 and the second data line group 37 that are located at opposite sides of the circuit column 22, the connection distance between the pixel circuit 3 and the first data line Data1 is the same as the connection distance between the pixel circuit 3 and the second data line Data2, which may reduce the difference in attenuation of the two types of data voltages during transmission.

In some embodiments, referring to FIG. 39 again, the same first data line Data1 is electrically connected to the pixel circuits 3 in the subpixels 2 of a same color, and the same second data line Data2 is electrically connected to the pixel circuits 3 in the subpixels 2 of a same color.

For the first data line group 32 and the second data line group 37 that are connected to a same circuit column 22, the arrangement order of multiple second data lines Data2 in the second data line group 37 is the same as the arrangement order of multiple first data lines Data1 in the first data line group 32.

Similar to the “first data line Data1”, when the same second data line Data2 is electrically connected to the pixel circuits 3 in the subpixels 2 of a same color, each second data line Data2 also corresponds to one color, and the color corresponding to the second data line Data2 is the same as the color corresponding to a pixel circuit 3 connected to the second data line Data2. Therefore, the arrangement order of multiple second data lines Data2 in the second data line group 37 may also be represented by the arrangement order of colors.

For example, referring to FIG. 39, the multiple second data lines Data2 in the second data line group 37 include a fourth data sub-line Data2-1, a fifth data sub-line Data2-2, and a sixth data sub-line Data2-3. The fourth data sub-line Data2-1 is electrically connected to the first pixel circuit 3-1 and corresponds to red color, the fifth data sub-line Data2-2 is electrically connected to the second pixel circuit 3-2 and corresponds to the green color, and the sixth data sub-line Data2-3 is electrically connected to the third pixel circuit 3-3 and corresponds to blue color.

That is, “for the first data line group 32 and the second data line group 37 that are connected to the same circuit column 22, the arrangement order of multiple second data lines Data2 in the second data line group 37 is the same as the arrangement order of multiple first data lines Data1 in the first data line group 32” may also be expressed as “for the first data line group 32 and the second data line group 37 that are connected to the same circuit column 22, the arrangement order of multiple colors corresponding to multiple second data lines Data2 in the second data line group 37 is the same as the arrangement order of multiple colors corresponding to multiple first data lines Data1 in the first data line group 32. The color corresponding to the first data line Data1 is the same as the color corresponding to the pixel circuit 3 connected to the first data line Data1, and the color corresponding to the second data line Data2 is the same as the color corresponding to the pixel circuit 3 connected to the second data line Data2.”

In the above configuration, the first data lines Data1 in the first data line group 32 and the second data lines Data2 in the second data line group 37 are arranged in a same order, making the arrangement of data lines more regular and simplifying the design of the connection line between the pixel circuit 3 and the data line.

In other embodiments of the present disclosure, for the first data line group 32 and the second data line group 37 that are connected to the same circuit column 22, the arrangement order of multiple colors corresponding to multiple second data lines Data2 in the second data line group 37 may also be different from the arrangement order of multiple colors corresponding to multiple first data lines Data1 in the first data line group 32.

In some embodiments, referring to FIGS. 36 and 38, the pixel circuit 3 is electrically connected to the second data line Data2 through the second connecting line 40, the second connecting line 40 and the first connecting line 35 are located at opposite sides of the pixel circuit 3 in the second direction y, and the second connecting line 40 may be arranged in the same layer as the first connecting line 35.

Referring to FIGS. 36 and 38, for the pixel 1 and the second data line group 37 that are connected to each other, regardless of whether the arrangement order of multiple colors corresponding to multiple pixel circuits 3 in the pixel 1 is the same as or different from the arrangement order of multiple colors corresponding to multiple second data lines Data2 in the second data line group 37, there will be no position conflicts among multiple second data lines Data2 when the pixel circuit 3 is connected to its corresponding second data line Data2 through the second connecting line 40, reaching a flexible arrangement of the second connecting lines 40.

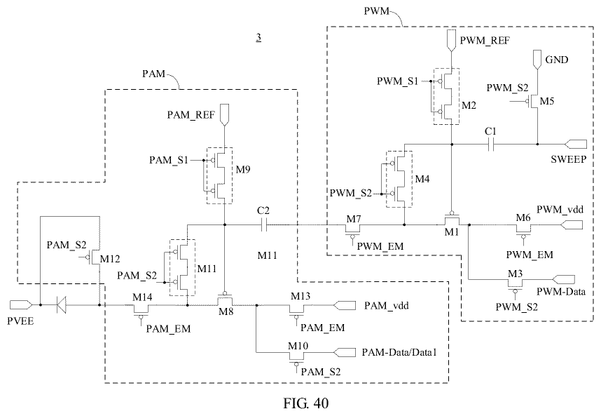

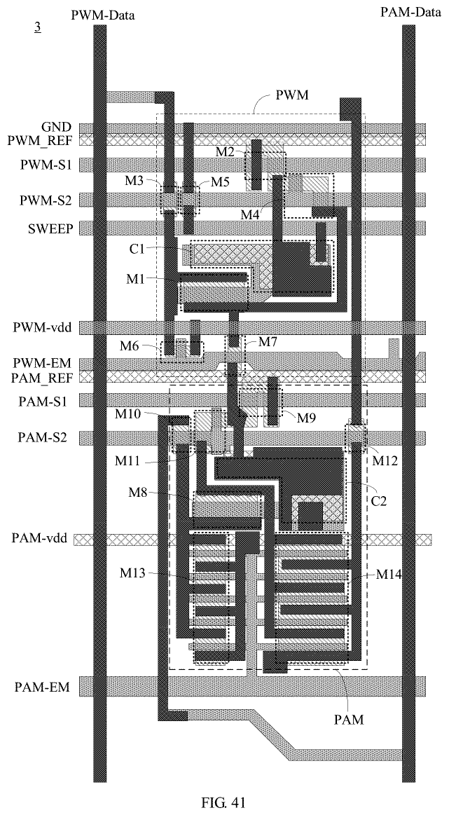

FIG. 40 illustrates a schematic diagram of a circuit structure of a pixel circuit 3 provided by embodiments of the present disclosure. FIG. 41 illustrates a schematic diagram of a layer structure of the pixel circuit 3 provided by embodiments of the present disclosure. In some embodiments, as shown in FIG. 40, the pixel circuit 3 includes a pulse width modulation circuit PWM and a pulse amplitude modulation circuit PAM. The first data line Data1 in the first data line group 32 is electrically connected to one of the pulse width modulation circuit PWM or the pulse amplitude modulation circuit PAM. This disclosure illustrates the first data line Data1 being electrically connected to the pulse amplitude modulation circuit PAM.

The pulse amplitude modulation circuit PAM is configured to adjust a light-emitting duty cycle of the light-emitting element 4, which is a duration of a light-emitting period of the light-emitting element 4. The pulse amplitude modulation circuit PAM is configured to control amplitude of a driving current. Both the pulse width modulation circuit PWM and the pulse amplitude modulation circuit PAM are configured to adjust the grayscale or brightness displayed by the light-emitting element 4.

In the following, embodiments of the present disclosure take FIG. 40 as an example to illustrate a circuit structure of the pixel circuit 3.

The pulse width modulation circuit PWM may include a first driving transistor M1, a first gate reset transistor M2, a first data write transistor M3, a first compensation transistor M4, a first capacitor C1, a control transistor M5, a first light-emitting control transistor M6, and a second light-emitting control transistor M7.

The first gate reset transistor M2 includes a gate electrically connected to a first scanning line PWM-S1, a first electrode electrically connected to a first reset signal line PAWM-REF, and a second electrode electrically connected to the gate of the first driving transistor M1.

The first data write transistor M3 includes a gate electrically connected to a second scanning line PWM-S2, a first electrode electrically connected to a pulse width modulation data line PWM-Data, and a second electrode electrically connected to the first electrode of the first driving transistor M1.

The first compensation transistor M4 includes a gate electrically connected to the second scanning line PWM-S2, a first electrode electrically connected to the second electrode of the first driving transistor M1, and a second electrode electrically connected to the gate of the first driving transistor M1.

The first capacitor C1 includes a first plate electrically connected to a frequency scanning signal line SWEEP, and a second plate electrically connected to the gate of the first driving transistor M1.

The control transistor M5 includes a gate electrically connected to the second scanning line PWM-S2, a first electrode electrically connected to a ground signal line GND, and a second electrode electrically connected to the first plate of the first capacitor C1.

The first light-emitting control transistor M6 includes a gate electrically connected to a first light-emitting control signal line PWM-EM, a first electrode electrically connected to a first fixed potential signal line PWM-vdd, and a second electrode electrically connected to the first electrode of the first driving transistor M1.

The second light-emitting control transistor M7 includes a gate electrically connected to the first light-emitting control signal line PWM-EM, and a first electrode electrically connected to the second electrode of the first driving transistor M1.

The pulse amplitude modulation circuit PAM may include a second capacitor C2, a second driving transistor M8, a second gate reset transistor M9, a second data write transistor M10, a second compensation transistor M11, an anode reset transistor M12, a third light-emitting control transistor M13, and a fourth light-emitting control transistor M14.

The second capacitor C2 includes a first plate electrically connected to the second electrode of the second light-emitting control transistor M7.

The second driving transistor M8 includes a gate electrically connected to the second plate of the second capacitor C2.

The second gate reset transistor M9 includes a gate electrically connected to a third scanning line PAM-S1, a first electrode electrically connected to a second reset signal line PAM-REF, and a second electrode electrically connected to the gate of the second driving transistor M8.

The second data write transistor M10 includes a gate electrically connected to a fourth scanning line PAM-S2, a first electrode electrically connected to a pulse amplitude modulation data line PAM-Data, and a second electrode electrically connected to the first electrode of the second driving transistor M8.

The second compensation transistor M11 includes a gate electrically connected to the fourth scanning line PAM-S2, a first electrode electrically connected to the second electrode of the second driving transistor M8, and a second electrode electrically connected to the gate of the second driving transistor M8.

The anode reset transistor M12 includes a gate electrically connected to the fourth scan line PAM-S2, a first electrode electrically connected to a first power supply signal line PVEE, and a second electrode electrically connected to the light-emitting element 4.

The third light-emitting control transistor M13 includes a gate electrically connected to a second light-emitting control signal line PAM-EM, a first electrode electrically connected to a second fixed potential signal line PAM-vdd, and a second electrode electrically connected to the first electrode of the second driving transistor M8.

The fourth light-emitting control transistor M14 includes a gate electrically connected to the second light-emitting control signal line PAM-EM, a first electrode electrically connected to the second electrode of the second driving transistor M8, and a second electrode electrically connected to the light-emitting element 4.

The first data line Data1 may serve as the pulse amplitude modulation data line PAM-Data, and a second data line Data2 may serve as the pulse width modulation data line PWM-Data.

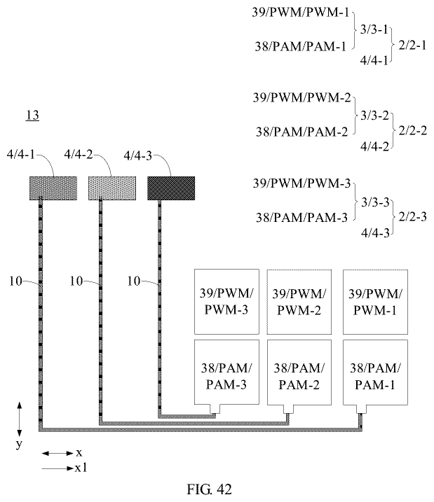

In some embodiments, as shown in FIG. 42, which illustrates another schematic diagram of a display panel provided by embodiments of the present disclosure, the pixel circuit 3 includes a first driving circuit 38, which serves as the pulse width modulation circuit PWM and/or the pulse amplitude modulation circuit PAM. The following embodiments of the present disclosure illustrate the case where the first driving circuit 38 is the pulse amplitude modulation circuit PAM.

In the first pixel 13, the pixel circuit 3 is electrically connected to the light-emitting element 4 through the first connection portion 10, and the first connection portion 10 is led out from the first driving circuit 38, and the order of the pixel circuits 3 is an order of the first driving circuits 38.

The first driving circuit 38 is a circuit in the pixel circuit 3 that is electrically connected to the light-emitting element 4. Therefore, the order of the pixel circuits 3 is represented by the order of the first driving circuits 38, which reflects the impact of adjusting the arrangement order of the pixel circuits 3 on the wiring method of the first connection portions 10.

Both the order of the pixel circuits 3 and the order of the first driving circuits 38 may be reflected by the order of their corresponding colors. For instance, referring to FIG. 42, in the first pixel circuit 3-1, the pulse amplitude modulation circuit PAM is a first pulse amplitude modulation circuit PAM-1 and the pulse width modulation circuit PWM is a first pulse width modulation circuit PWM-1; in the second pixel circuit 3-2, the pulse amplitude modulation circuit PAM is a second pulse amplitude modulation circuit PAM-2 and the pulse width modulation circuit PWM is a second pulse width modulation circuit PWM-2; and in the third pixel circuit 3-3, the pulse amplitude modulation circuit PAM is a third pulse amplitude modulation circuit PAM-3 and the pulse width modulation circuit PWM is a third pulse width modulation circuit PWM-3.

When the first driving circuit 38 is a pulse amplitude modulation circuit PAM, the first pixel circuit 3-1, the second pixel circuit 3-2, and the third pixel circuit 3-3 are arranged sequentially, which implies that the first pulse amplitude modulation circuit PAM-1, the second pulse amplitude modulation circuit PAM-2, and the third pulse amplitude modulation circuit PAM-3 are also arranged sequentially.

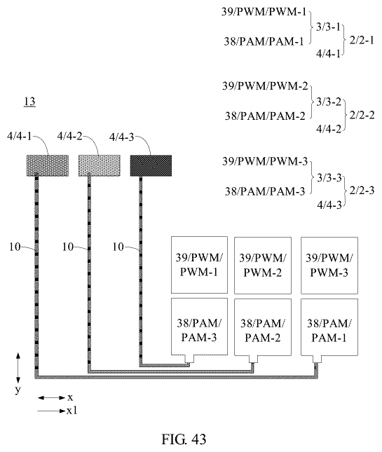

In some embodiments, as shown in FIG. 43, which is another schematic diagram of a display panel provided by embodiments of the present disclosure, the pixel circuit 3 includes a first driving circuit 38 and a second driving circuit 39, the first driving circuit 38 is one of the pulse width modulation circuit PWM and the pulse amplitude modulation circuit PAM, and the second driving circuit 39 is another one of the pulse width modulation circuit PWM and the pulse amplitude modulation circuit PAM. The embodiments of the present disclosure exemplify the case where the first driving circuit 38 is the pulse amplitude modulation circuit PAM, and the second driving circuit 39 is the pulse width modulation circuit PWM.

At least in the first pixel 13, the arrangement order of multiple first driving circuits 38 differs from the arrangement order of multiple second driving circuits 39. In other words, at least in the first pixel 13, the arrangement order of multiple colors corresponding to the multiple first driving circuits 38 differs from the arrangement order of multiple colors corresponding to the multiple second driving circuits 39. The color corresponding to the first driving circuit 38 is the same as the color of the light-emitting element 4 connected to the first driving circuit 38, and the color corresponding to the second driving circuit 39 is the same as the color of the light-emitting element 4 coupled to the second driving circuit 39.

In the first pixel 13, the pixel circuit 3 is electrically connected to the light-emitting element 4 through first connection portion 10, and the first connection portion 10 is led out from the first driving circuit 38. The order of the pixel circuits 3 is the order of the first driving circuits 38.

The first driving circuit 38 is a circuit in the pixel circuit 3, which is electrically connected to the light-emitting element 4. Therefore, the order of the pixel circuits 3 is represented by the order of the first driving circuits 38, which reflects the impact of adjusting the arrangement order of the pixel circuits 3 on the wiring method of the first connection portions 10. The second driving circuits 3 may be arranged in a different order from the first driving circuits 38, reaching a more flexible design.

In some embodiments, referring to FIG. 43, at least in the first pixel 13, the arrangement order of multiple colors corresponding to multiple first driving circuits 38 may also be the same as the arrangement order of multiple colors corresponding to multiple second driving circuits 39.

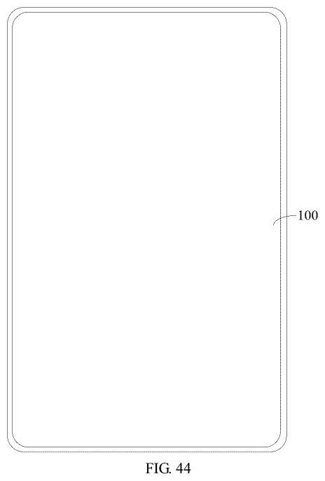

Based on the same concept, embodiments of the present disclosure further provide a display device, as shown in FIG. 44, which is a schematic diagram of a display device provided by embodiments of the present disclosure. The display device includes the display panel 100. The structure of the display panel 100 has been described in detail in the above embodiments and will not be repeated herein. The display device shown in FIG. 44 is merely illustrative, and the display device may be any electronic device with a display function, such as a mobile phone, a tablet computer, a laptop computer, an electronic paper book, or a television.

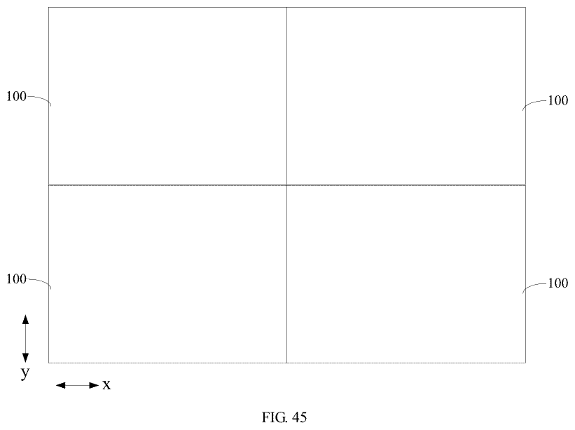

Based on the same concept, embodiments of the present disclosure further provide a display device, as shown in FIG. 45, which is a schematic diagram of a splicing display device provided by embodiments of the present disclosure. The splicing display device includes at least two display panels 100. In some embodiments, the at least two display panels 100 are arranged along a first direction x, and/or the at least two display panels 100 are arranged along a second direction y. The structure of the display panel 100 has been described in detail in the above embodiments and will not be repeated herein. The display device shown in FIG. 45 is merely illustrative, and the splicing display device may be any large-screen display device with a display function.

The above description merely illustrates some embodiments of the present disclosure and is not intended to limit the present disclosure. Any modifications, equivalent replacements, improvements, made within the principles of the present disclosure should be included within the scope of the present disclosure.

Finally, the above embodiments are only used to illustrate the technical solutions of the present disclosure, not to limit them. Although the present disclosure has been described in detail with reference to the above embodiments, it should be understood by those skilled in the art that they may still modify the technical solutions described in the above embodiments or replace some or all of the technical features with equivalent ones, and these modifications or replacements do not deviate from the scope of the technical solutions of the embodiments of the present disclosure.

What is claimed is:

1. A display panel, comprising:
pixels, wherein a pixel of the pixels comprises subpixels, and a subpixel of the subpixels comprises a pixel circuit and a light-emitting element that are electrically connected to each other;
wherein, in the pixel, the light-emitting elements of the subpixels are arranged along a first direction, and the pixel circuits of the subpixels are arranged along the first direction; and
wherein, in at least one pixel of the pixels, an arrangement order of the light-emitting elements is different from an arrangement order of the pixel circuits; or an arrangement order of the pixel circuits in one pixel of the pixels is different from an arrangement order of the pixel circuits in another pixel of the pixels; or an arrangement order of the light-emitting elements in one pixel of the pixels are different is different from an arrangement order the light-emitting elements in another pixel of the pixels.

2. The display panel according to claim 1, wherein the subpixels in the pixel comprise a first subpixel, a second subpixel, and a third subpixel;
in at least one pixel of the pixels, the light-emitting element of the first subpixel and the light-emitting element of the second subpixel are adjacent to each other, and the pixel circuit of the first subpixel and the pixel circuit of the second subpixel are adjacent to each other; and
an arrangement order of the light-emitting elements of the first subpixel and the second subpixel is opposite to an arrangement order of the pixel circuits of the first subpixel and the second subpixel.

3. The display panel according to claim 1, wherein the pixels comprise at least one first-type pixel and at least one second-type pixel;
a distance between the pixel circuit and the light-emitting element in one subpixel of the subpixels of one first-type pixel of the at least one first-type pixel is greater than a distance between the pixel circuit and the light-emitting element in one subpixel of the subpixels of one second-type pixel of the at least one second-type pixel;
at least in one second-type pixel of the at least one second-type pixel, an arrangement order of the light-emitting elements of the subpixels is the same as an arrangement order of pixel circuits of the subpixels; and
the at least one first-type pixel comprise at least one first pixel, and at least in one first pixel of the at least one first pixel, an arrangement order of the light-emitting elements of the subpixels is different from an arrangement order of the pixel circuits of the subpixels.

4. The display panel according to claim 3, wherein in at least one first pixel, an arrangement order of the light-emitting elements are opposite to an arrangement order of the pixel circuits.

5. The display panel according to claim 3, wherein the at least one first pixel comprises at least two first pixels, and an arrangement order of the light-emitting elements in one first pixel of the at least two first pixels is the same as an arrangement order of the light-emitting elements in another first pixel of the at least two first pixels, and an arrangement order of the pixel circuits in the one first pixel is the same as an arrangement order of the pixel circuits in the another first pixel.

6. The display panel according to claim 3, wherein an arrangement order of the light-emitting elements in the at least one first pixel is the same as the arrangement orders of the light-emitting elements in the at least one second-type pixel.

7. The display panel according to claim 3, wherein an arrangement order of the pixel circuits in the at least one first pixel is the same as the arrangement orders of the pixel circuits in the at least one second-type pixel.

8. The display panel according to claim 3, wherein the display panel has at least one first outer edge extending along the first direction;
in one first pixel of the at least one first pixel, the pixel circuits of the subpixels are electrically connected to the light-emitting elements of the subpixels through first connecting portions, wherein the first connecting portions extend from a side of the pixel circuits close to one first outer edge of the at least one first outer edge and are electrically connected to the light-emitting elements at a side close to the first outer edge.

9. The display panel according to claim 3, wherein the display panel has a display region comprising a first region and a second region, and the first region is located at a side of the second region close to an edge of the display panel;
wherein the at least one first-type pixel is located in the first region, and the at least one second-type pixel is located in the second region; and along at least one of the first direction or a second direction, a spacing between at least some adjacent pixel circuits of the pixel circuits in one first-type pixel of the at least one first-type pixel is smaller than a spacing between adjacent pixel circuits of the pixel circuits in one second-type pixel of the at least one second-type pixels, the second direction intersecting with the first direction.

10. The display panel according to claim 3, wherein in a direction perpendicular to a plane of the display panel, at least one pixel circuit of the pixel circuits in one first-type pixel of the at least one first-type pixel does not overlap with at least one light-emitting element, corresponding to the at least one pixel circuit, of the light-emitting elements in the first-type pixels, and at least one pixel circuit of the pixel circuits in one second-type pixel of the at least one first-type pixel overlaps with at least one light-emitting element, corresponding to the at least one pixel circuit, of the light-emitting elements in the second-type pixels.

11. The display panel according to claim 3, wherein the display panel has at least one first outer edge extending along the first direction;
in one first pixel of the at least one first pixel, the pixel circuit is electrically connected to the light-emitting element through a first connecting portion;
in the pixel, the light-emitting elements form a light-emitting unit, and the pixel circuits form a circuit unit;
the at least one first pixel comprises at least one first-type first pixel, in which an orthogonal projection of the light-emitting unit on a plane of the display panel and an orthogonal projection of the circuit unit on the plane of the display panel do not overlap in neither the first direction nor a second direction intersecting with the first direction; and an arrangement order of the light-emitting elements in the first-type first pixel is opposite to an arrangement order of the pixel circuits in the first-type first pixel; and
in one of the at least one first-type first pixel, a distance between the circuit unit and one first outer edge of the at least one first outer edge is smaller than a distance between the light-emitting unit and the first outer edge, and the first connecting portion corresponding to the first-type first pixel is led out from a side of the pixel circuit close to the first outer edge and then extends from a side of the circuit unit close to the light-emitting unit in the first direction to a side of the light-emitting element close to the first outer edge to be electrically connected to the light-emitting element; and/or,
in one first-type first pixel of the at least one first-type first pixel, the distance between the circuit unit and the first outer edge is greater than the distance between the light-emitting unit and the first outer edge, and the first connecting portion corresponding to the first-type first pixel is led out from the side of the pixel circuit close to the first outer edge and then extends from a side of the light-emitting unit close to the circuit unit in the first direction to the side of the light-emitting element close to the first outer edge to be electrically connected to the light-emitting element.

12. The display panel according to claim 3, wherein the display panel has at least one first outer edge extending along the first direction;
in one first pixel of the at least one first pixel, the pixel circuit is electrically connected to the light-emitting element through a first connecting portion;
in the pixel, the light-emitting elements form a light-emitting unit, and the pixel circuits form a circuit unit;
the at least one first pixel comprises a second-type first pixel in which an orthogonal projection of the light-emitting unit on a plane of the display panel and an orthogonal projection of the circuit unit on the plane of the display panel do not overlap in the first direction and overlap in a second direction intersecting with the first direction, and an orthogonal projection of at least one pixel circuit of the pixel circuits in the second-type first pixel on the plane of the display panel and an orthogonal projection of at least one light-emitting element of the light-emitting elements in the second-type first pixel on the plane of the display panel do not overlap; and an arrangement order of the light-emitting elements in the second-type first pixel is opposite to an arrangement order of the pixel circuits in the second-type first pixel; and
in one second-type first pixel of the at least one second-type first pixel, a distances between the circuit unit and the first outer edge is smaller than a distance between the light-emitting unit and the first outer edge, and the first connecting portion corresponding to the second-type first pixel is led out from a side of the pixel circuit close to the first outer edge and then extends from a side of the circuit unit in the first direction to a side of the light-emitting element close to the first outer edge to be electrically connected to the light-emitting element; and/or,
in one second-type first pixel of the at least one second-type first pixel, the distance between the circuit unit and the first outer edge is greater than the distance between the light-emitting unit and the first outer edge, and the first connecting portion corresponding to the second-type first pixel is led out from the side of the pixel circuit close to the first outer edge and then extends from a side of the light-emitting unit in the first direction to the side of the light-emitting element close to the first outer edge to be electrically connected to the light-emitting element.

13. The display panel according to claim 3, wherein the display panel has at least one first outer edge extending along the first direction;
in one first pixel of the at least one first pixel, the pixel circuit is electrically connected to the light-emitting element through a first connecting portion;
in the pixel, the light-emitting elements form a light-emitting unit, and the pixel circuits form a circuit unit;
the at least one first pixel comprises a third-type first pixel in which the light-emitting unit and the circuit unit are arranged along the first direction;
in the third-type first pixel, an arrangement order of the light-emitting elements is opposite to an arrangement order of the pixel circuits; and
the first connecting portion corresponding to the third-type first pixel is led out from a side of pixel circuits close to the first outer edge, and then extends to a side of light-emitting element close to the first outer edge to be electrically connected with to the light-emitting element.

14. The display panel according to claim 3, wherein the display panel has at least one first outer edge extending along the first direction;
in one first pixel of the at least one first pixel, the pixel circuit is electrically connected to the light-emitting element through a first connecting portion;
in the pixel, the light-emitting elements form a light-emitting unit, and the pixel circuits form a circuit unit;
the at least one first pixel comprises a fourth-type first pixel in which the light-emitting unit and the circuit unit overlap in a direction perpendicular to a plane of the display panel and at least one pixel circuit of the pixel circuits and at least one light-emitting element of the light-emitting elements corresponding to the at least one pixel circuit do not overlap; and an arrangement order of the light-emitting elements in the fourth-type first pixels is opposite to an arrangement order of the pixel circuits in the fourth-type first pixels; and
the first connecting portion corresponding to the fourth-type first pixel is led out from a side of the pixel circuit close to the first outer edge and then extends to a side of light-emitting element close to the first outer edge to be electrically connected to the light-emitting element.

15. The display panel according to claim 3, wherein in the pixel, the light-emitting elements form a light-emitting unit, and the pixel circuits form a circuit unit;
the at least one first-type pixel further comprises at least one second pixel, in one second pixel of the at least one second pixels, an orthographic projection of the light-emitting unit on a plane of the display panel and an orthographic projection of the circuit unit on the plane of the display panel do not overlap, and in the second pixel, an arrangement order of the light-emitting elements is the same as an arrangement order of the pixel circuits; and
in the second pixel, the pixel circuit is electrically connected to the light-emitting element through a second connecting portion, and the second connecting portion extends from a side of the pixel circuit close to the light-emitting unit in a second direction and is electrically connected to the light-emitting element at a side of the light-emitting element close to the circuit unit in the second direction, the second direction intersecting with the first direction.

16. The display panel according to claim 15, wherein a pattern of the pixel circuit in one of the at least second pixel after being flipped with the first direction as axis is the same as a pattern of the pixel circuit in the second-type pixel.

17. The display panel according to claim 15, wherein in one of the at least one second pixel, a side of the pixel circuit close to the light-emitting unit in the second direction is a side of the pixel circuit close to an edge of the display panel in the second direction.

18. The display panel according to claim 3, wherein the pixel circuits in the pixel form a circuit unit, and the circuit units in at least two pixels of the pixels are arranged along a second direction to form one circuit column of at least one circuit column, the second direction intersecting with the first direction;
the display panel further comprises first data line groups, wherein one first data line group of the first data line groups corresponds to one circuit column of the at least one circuit column, and is located at a side of the circuit column in the first direction; and
one first data line group of the first data line groups comprises first data lines arranged along the first direction, and the pixel circuits of the circuit unit in one circuit column of the at least one circuit column are respectively electrically connected to first data lines in one first data line group of the first data line groups corresponding to the pixel circuits.

19. The display panel according to claim 18, wherein one first data line of the first data line is electrically connected to the pixel circuits in at least two subpixels, of a same color, of the subpixels;
an arrangement order of the first data lines in one first data line group of the first data line groups is the same as an arrangement order of the pixel circuits in one second-type pixel of the at least one second-type pixel.

20. The display panel according to claim 18, wherein one first data line of the first data line is electrically connected to the pixel circuits in at least two subpixels, of a same color, of the subpixels;
the at least one circuit column comprises at least one first circuit column and at least one second circuit column, and the first data line groups comprise at least one first-type first data line group electrically connected to the at least one first circuit column and at least one second-type first data line group electrically connected to the at least one second circuit column; and
an arrangement order of the first data lines in one first-type first data line group of the at least one first-type first data line group is different from an arrangement order of the first data lines in one second-type first data line group of the at least one second-type first data line group.

21. The display panel according to claim 20, wherein an arrangement order of the pixel circuits in one first pixel of the at least one first pixel is different from an arrangement order of the pixel circuits in one second-type pixel of the at least one second-type pixel;
one first circuit column of the at least one first circuit column comprises the pixel circuits in the first pixel, and one second circuit column of the at least one second circuit column comprises the pixel circuits in the second-type pixel; and
an arrangement order of the first data lines in the first-type first data line group is the same as an arrangement order of the pixel circuits in one first pixel of the at least one first pixel, and an arrangement order of the first data lines in the second-type first data line group is the same as an arrangement order of the pixel circuits in the second-type pixel.

22. The display panel according to claim 18, wherein the pixel circuit is electrically connected to one first data line of the first data lines through a first connecting line, the first connecting line is located at a side of the pixel circuit in the second direction, and the first connecting line is arranged in a layer different from the first data lines.

23. The display panel according to claim 18, wherein the display panel further comprises second data line groups, wherein one second data line group of the second data line groups corresponds to one circuit column of the at least one circuit column, one second data line group of the second data line groups comprises second data lines arranged along the first direction, pixel circuits of the circuit unit in the circuit column are respectively electrically connected to the second data lines of one second data line group, corresponding to the pixel circuits, of the second data line groups; and
for one first data line group of the first data line groups and one second data line group of the second data line groups that are connected to the one circuit column of the at least one circuit column, the first data line group and the second data line group are respectively located at opposite sides of the circuit column, and the first data line groups and the second data line groups are alternately arranged in the first direction.

24. The display panel according to claim 23, wherein one first data line of the first data lines is electrically connected to at least two of the pixel circuits in at least two subpixels, of a same color, of the subpixels, and one second data line of the second data lines is electrically connected to at least two of the pixel circuits in at least two subpixels, of a same color, of the subpixels; and
for one first data line group of the first data line groups and one second data line group of the second data line groups that are connected to one circuit column of the at least one circuit column, an arrangement order of the second data lines in the second data line group is the same as an arrangement order of the first data lines in the first data line group.

25. The display panel according to claim 18, wherein a pixel circuit comprises a pulse width modulation circuit and an amplitude adjustment circuit, and a first data line in a first data line group is electrically connected to one of the pulse width modulation circuit and the amplitude adjustment circuit.

26. The display panel according to claim 3, wherein the pixel circuit comprises a first driving circuit, wherein the first driving circuit is a pulse width modulation circuit or an amplitude adjustment circuit; and
in one first pixel of the at least one first pixel, the pixel circuit is electrically connected to the light-emitting element through a first connection portion, the first connection portion is led out from the first driving circuit, and an order of the pixel circuits in the first pixel is an order of the first driving circuits of the pixel circuits in the first pixel.

27. The display panel according to claim 3, wherein the pixel circuit comprises a first driving circuit and a second driving circuit, wherein the first driving circuit is one of a pulse width modulation circuit and an amplitude adjustment circuit, and the second driving circuit is another one of the pulse width modulation circuit and the amplitude adjustment;
at least in one first pixel of the at least one first pixel, an arrangement order of the first driving circuits of the pixel circuits is different from an arrangement order of the second driving circuits of the pixel circuits; and
in the first pixel, the pixel circuit is electrically connected to the light-emitting element through a first connection portion, the first connection portion is led out from the first driving circuit, and an order of the pixel circuits in the first pixel is an order of the first driving circuits in the first pixel.

28. A display device, comprising a display panel,
wherein the display panel comprises pixels, wherein a pixel of the pixels comprises subpixels, and a subpixel of the subpixels comprises a pixel circuit and a light-emitting element that are electrically connected to each other;
wherein, in the pixel, the light-emitting elements of the subpixels are arranged along a first direction, and the pixel circuits of the subpixels are arranged along the first direction; and
wherein, in at least one pixel of the pixels, an arrangement order of the light-emitting elements is different from an arrangement order of the pixel circuits; or an arrangement order of the pixel circuits in one pixel of the pixels is different from an arrangement order of the pixel circuits in another pixel of the pixels; or an arrangement order of the light-emitting elements in one pixel of the pixels are different is different from an arrangement order the light-emitting elements in another pixel of the pixels.

29. A splicing display device, comprising at least two display panels, wherein the at least two display panels comprises pixels, wherein a pixel of the pixels comprises subpixels, and a subpixel of the subpixels comprises a pixel circuit and a light-emitting element that are electrically connected to each other;
wherein, in the pixel, the light-emitting elements of the subpixels are arranged along a first direction, and the pixel circuits of the subpixels are arranged along the first direction; and
wherein, in at least one pixel of the pixels, an arrangement order of the light-emitting elements is different from an arrangement order of the pixel circuits; or an arrangement order of the pixel circuits in one pixel of the pixels is different from an arrangement order of the pixel circuits in another pixel of the pixels; or an arrangement order of the light-emitting elements in one pixel of the pixels are different is different from an arrangement order the light-emitting elements in another pixel of the pixels.
